(19) United States
(12) Patent Application Publication
(10) Pub. No.: US 2023/0402570 A1
(43) Pub. Date: Dec. 14, 2023

(54) DISPLAY DEVICE

(71) Applicant: Samsung Display Co., LTD., Yongin-si (KR)

(72) Inventors: Byeong Hoon CHO, Yongin-si (KR); Hyun KIM, Yongin-si (KR); Jin Taek KIM, Yongin-si (KR)

(73) Assignee: Samsung Display Co., LTD., Yongin-si (KR)

(21) Appl. No.: 18/116,944

(22) Filed: Mar. 3, 2023

(30) Foreign Application Priority Data
Jun. 9, 2022 (KR) 10-2022-0070355

(51) Int. Cl. H01L 33/38; H01L 33/62; H01L 33/50; H01L 25/075

(52) U.S. Cl. CPC H01L 33/382; H01L 33/62; H01L 33/505; H01L 25/0753

(57) ABSTRACT

A display device includes a first bank defining an emission area, a first bank pattern, a second bank pattern, and a third bank pattern, each disposed in the emission area, arranged in a first direction, and extending in a second direction intersecting the first direction, a first electrode, a second electrode, and a third electrode respectively overlapping the first, second, and third bank patterns in a plan view, and light emitting elements arranged between the first electrode and the second electrode and between the second electrode and the third electrode. The second bank pattern is discontinuously disposed.

### CROSS-REFERENCE TO RELATED APPLICATION(S)

This application claims priority to and benefits of Korean patent application No. 10-2022-0070355 under 35 U.S.C. § 119(a), filed on Jun. 9, 2022, in the Korean Intellectual Property Office (KIPO), the entire contents of which are incorporated herein by reference.

### BACKGROUND

### 1. Technical Field

The disclosure relates to a display device.

### 2. Description of the Related Art

As interest in information displays and demand for portable information media increase, research and commercialization has focused on display devices.

### SUMMARY

Embodiments provide a display device capable of reducing a luminance variation.

In accordance with an aspect of the disclosure, a display device may include a first bank defining an emission area; a first bank pattern, a second bank pattern, and a third bank pattern, each disposed in the emission area, arranged in a first direction, and extending in a second direction intersecting the first direction; a first electrode, a second electrode, and a third electrode, respectively overlapping the first, second, and third bank patterns in a plan view; and light emitting elements arranged between the first electrode and the second electrode and between the second electrode and the third electrode. The second bank pattern may be discontinuously disposed.

The second bank pattern may include at least one discontinuous area.

The at least one discontinuous area may be located at a center of the emission area.

A length of the at least one discontinuous area in the second direction may be in a range of about two times to about five times of a length of each of the light emitting elements.

The second bank pattern may include a first sub-pattern and a second sub-pattern, which are spaced apart from each other in the first direction.

The second electrode may continuously extend from the first sub-pattern to the second sub-pattern and cover an area between the first sub-pattern and the second sub-pattern.

A distance between the first sub-pattern and the second sub-pattern in the second direction may be in a range of about two times to about five times of a length of each of the light emitting elements.

The distance between the first sub-pattern and the second sub-pattern may be in a range of about 10 μm to about 20 μm.

The display device may further include a first contact electrode overlapping the first electrode in a plan view and electrically connected to first end portions of some of the light emitting elements, and a second contact electrode overlapping the second electrode in a plan view and electrically connected to second end portions of the some of the light emitting elements.

The second contact electrode may have a bent shape in an area between the first sub-pattern and the second sub-pattern in a plan view.

The display device may further include an insulating layer disposed between the first and second contact electrodes and the first and second electrodes. The first and second contact electrodes may be electrically insulated from the first and second electrodes.

At least one of the first and second sub-patterns may overlap the first bank in a plan view.

The first and second sub-patterns may be spaced apart from the first bank in a plan view.

The display device may further include a color conversion pattern disposed on the light emitting elements, converting a wavelength band of light incident from the light emitting elements, and emitting the light having the converted wavelength band, and a color filter disposed on the color conversion pattern.

In accordance with another aspect of the disclosure, a display device may include: a first bank pattern, a second bank pattern, and a third bank pattern, each disposed in an emission area, arranged in a first direction, and extending in a second direction intersecting the first direction; a first electrode, a second electrode, and a third electrode, respectively disposed on the first, second, and third bank patterns; a first bank disposed on the first to third electrodes and defining the emission area; and light emitting elements arranged between the first electrode and the second electrode and between the second electrode and the third electrode. Light emitted from the light emitting elements may be reflected by the first to third electrodes on the first to third bank patterns to advance in a third direction intersecting the first direction and the second direction. The second bank pattern may include a portion, and the portion of the second bank pattern and another portion of the second bank pattern may have different thicknesses in the third direction.

A thickness of the portion of the second bank pattern in the third direction may be less than an average thickness of the second bank pattern in the third direction.

The thickness of the portion of the second bank pattern may be less than or equal to about 40% of a thickness of the another part of the second bank pattern in the third direction.

A length of the portion of the second bank pattern in the second direction may be in a range of about two times to about five times of a length of each of the light emitting elements.

The second bank pattern may overlap the first bank in a plan view and extend across the emission area.

The display device may further include a color conversion pattern disposed on the light emitting elements, converting a wavelength band of the light emitted from the light emitting elements, and emitting the light having the converted wavelength band, and a color filter disposed on the color conversion pattern.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure.

FIG. 1 is a perspective view illustrating a light emitting element in accordance with an embodiment of the disclosure.

FIG. 2 is a schematic cross-sectional view illustrating the light emitting element in accordance with the embodiment of the disclosure.

FIG. 3 is a plan view illustrating a display device in accordance with an embodiment of the disclosure.

FIG. 4A is a schematic diagram of an equivalent circuit of a sub-pixel in the display device shown in FIG. 3 in accordance with an embodiment of the disclosure.

FIG. 4B is a schematic diagram of an equivalent circuit of a sub-pixel in the display device shown in FIG. 3 in accordance with an embodiment of the disclosure.

FIG. 5 is a plan view illustrating an embodiment of a pixel included in the display device shown in FIG. 3.

FIG. 6A is a plan view illustrating an embodiment of the pixel shown in FIG. 5.

FIG. 6B is a plan view illustrating another embodiment of the pixel shown in FIG. 5.

FIG. 7 is a schematic cross-sectional view illustrating an embodiment of a first sub-pixel taken along line I-I′ shown in FIG. 5.

FIG. 8 is a schematic cross-sectional view illustrating an embodiment of the first sub-pixel taken along line II-II′ shown in FIG. 5.

FIG. 9 is a schematic cross-sectional view illustrating a manufacturing process of the first sub-pixel shown in FIG. 8.

FIG. 10A is schematic cross-sectional views of the first sub-pixel taken along the line I-I′ shown in FIG. 5 in accordance with an embodiment of the disclosure.

FIG. 10B is schematic cross-sectional views of the first sub-pixel taken along the line I-I′ shown in FIG. 5 in accordance with an embodiment of the disclosure.

FIG. 10C is schematic cross-sectional views of the first sub-pixel taken along the line I-I′ shown in FIG. 5 in accordance with an embodiment of the disclosure.

FIG. 11 is a plan view illustrating a comparative embodiment of the pixel included in the display device shown in FIG. 3.

FIG. 12 is a view illustrating an image obtained by photographing the pixel shown in FIG. 11.

FIGS. 13 and 14 are plan views illustrating another embodiment of the pixel included in the display device shown in FIG. 3.

FIG. 15 is a plan view illustrating another embodiment of the pixel included in the display device shown in FIG. 3.

FIG. 16 is a schematic cross-sectional view illustrating an embodiment of a first sub-pixel taken along line IV-IV′ shown in FIG. 15.

### DETAILED DESCRIPTION OF THE EMBODIMENTS

Embodiments will now be described more fully hereinafter with reference to the accompanying drawings; however, they may be embodied in different forms and should not be construed as limited to the embodiments set forth herein. Rather, these embodiments are provided so that this disclosure will be more thorough and complete, and will fully convey the scope of the embodiments to those skilled in the art.

The disclosure may apply various changes and different shape, therefore only illustrate in detail with particular examples. However, the examples do not limit to certain shapes but apply to all the change and equivalent material and replacement. The drawings included are illustrated a fashion where the figures are expanded for the better understanding.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

It will be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

The effects and characteristics of the disclosure and a method of achieving the effects and characteristics will be clear by referring to the embodiments described below in detail together with the accompanying drawings. However, the disclosure is not limited to the embodiments disclosed herein but may be implemented in various forms.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

In the specification and the claims, the phrase “at least one of” is intended to include the meaning of “at least one selected from the group of” for the purpose of its meaning and interpretation. For example, “at least one of A and B” may be understood to mean “A, B, or A and B.”

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, a display device in accordance with an embodiment of the disclosure will be described with reference to the accompanying drawings.

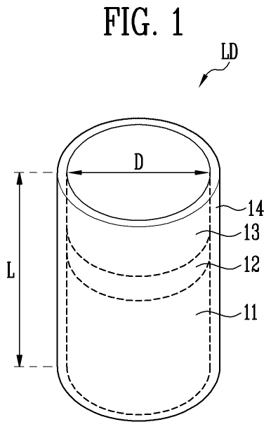

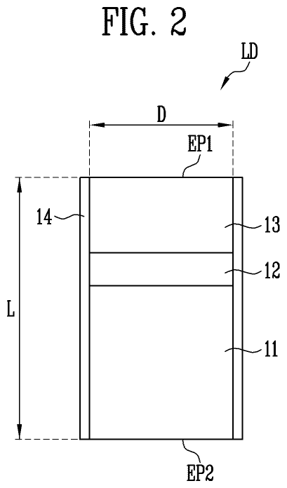

FIG. 1 is a perspective view illustrating a light emitting element in accordance with an embodiment of the disclosure. FIG. 2 is a schematic cross-sectional view illustrating the light emitting element in accordance with the embodiment of the disclosure. Although a pillar-shaped light emitting element LD is illustrated in FIGS. 1 and 2, the kind and/or shape of the light emitting element LD is not limited thereto.

Referring to FIGS. 1 and 2, the light emitting element LD may include a first semiconductor layer 11, an active layer 12, and a second semiconductor layer 13. In case that an extending direction of the light emitting element LD is a length L direction, the first semiconductor layer 11, the active layer 12, and the second semiconductor layer 13 may be sequentially stacked in the length L direction.

The light emitting element LD may be provided in a pillar shape extending in a direction. The light emitting element LD may have a first end portion EP1 and a second end portion EP2. One of the first and second semiconductor layers 11 and 13 may be disposed at the first end portion EP1 of the light emitting element LD. Another one of the first and second semiconductor layers 11 and 13 may be disposed at the second end portion EP2 of the light emitting element LD.

In some embodiments, the light emitting element LD may be a light emitting element manufactured in a pillar shape through an etching process, or the like. In this specification, the term “pillar shape” may include a rod-like shape or bar-like shape, which is long in the length L direction (i.e., its aspect ratio is greater than 1), such as a cylinder or a polyprism, and the cross-sectional shape is not particularly limited. For example, a length L of the light emitting element LD may be greater than a diameter D (or a width in a cross-sectional view) of the light emitting element LD.

The light emitting element LD may have a size of nanometer scale to micrometer scale. In an embodiment, the light emitting element LD may have a diameter D (or width) in a range of nanometer scale to micrometer scale and/or a length L in a range of nanometer scale to micrometer scale. However, the size of the light emitting element LD is not limited thereto, and the size of the light emitting element LD may be variously changed according to design conditions of various types of devices, e.g., a display device, and the like, which use, as a light source, a light emitting device using the light emitting element LD.

The first semiconductor layer 11 may be a first conductivity type semiconductor layer. For example, the first semiconductor layer 11 may include an n-type semiconductor layer. In an embodiment, the first semiconductor layer 11 may include at least one semiconductor material such as InAlGaN, GaN, AlGaN, InGaN, AlN, and InN, and include an n-type semiconductor layer doped with a first conductivity type dopant such as Si, Ge, and Sn. However, the material constituting the first semiconductor layer 11 is not limited thereto. The first semiconductor layer 11 may be formed of various materials.

The active layer 12 may be formed on the first semiconductor layer 11, and may be formed in a single-quantum well structure or a multi-quantum well structure. The active layer 12 may include GaN, InGaN, InAlGaN, AlGaN, AlN or the like. The active layer 12 may be formed of various materials. In some embodiments, a clad layer (not shown) doped with a conductive dopant may be formed on the top and/or the bottom of the active layer 12. In an embodiment, the clad layer may include an AlGaN layer or InAlGaN layer.

The second semiconductor layer 13 may be formed on the active layer 12, and may include a semiconductor layer having a type different from that of the first semiconductor layer 11. For example, the second semiconductor layer 13 may include a p-type semiconductor layer. In an embodiment, the second semiconductor layer 13 may include at least one semiconductor material such as InAlGaN, GaN, AlGaN, InGaN, AlN, and InN, and include a p-type semiconductor layer doped with a second conductivity type dopant such as Mg. However, the material constituting the second semiconductor layer 13 is not limited thereto. The second semiconductor layer 13 may be formed of various materials.

In case that a voltage of a threshold voltage or more is applied to both ends of the light emitting element LD, the light emitting element LD may emit light as electron-hole pairs are combined in the active layer 12. The light emission of the light emitting element LD may be controlled by using such a principle, so that the light emitting element LD can be used as a light source for various light emitting devices, including a pixel of a display device.

The light emitting element LD may further include an insulative film 14 provided on a surface thereof. The insulative film 14 may be formed on the surface of the light emitting element LD to surround an outer circumferential surface of at least the active layer 12. The insulative film 14 may further surround at least a portion of circumferential surfaces of each of the first and second semiconductor layers 11 and 13.

In some embodiments, the insulative film 14 may expose both end portions EP1 and EP2 of the light emitting element LD, which have different polarities. For example, the insulative film 14 may expose an end of each of the first and second semiconductor layers 11 and 13 located at the first and second end portions EP1 and EP2 of the light emitting element LD. In another embodiment, the insulative film 14 may expose a side portion of each of the first and second semiconductor layers 11 and 13 adjacent to the first and second end portions EP1 and EP2 of the light emitting element LD, which have different polarities.

In some embodiments, the insulative film 14 may be configured as a single layer or a multi-layer (e.g., a double layer formed of aluminum oxide (AlOₓ) and silicon oxide (SiOₓ)), including at least one insulating material such as silicon oxide (SiOₓ), silicon nitride (SiNₓ), silicon oxynitride (SiOₓN_{y}), aluminum oxide (AlOₓ), and titanium oxide (TiOₓ), but the disclosure is not limited thereto. For example, in accordance with another embodiment, the insulative film 14 may be omitted.

In case that the insulative film 14 is provided to cover the surface of the light emitting element LD, for example, the outer circumferential surface of the active layer 12, the active layer 12 may be prevented from being short-circuited with a first pixel electrode, a second pixel electrode, or the like, which will be described later. Accordingly, the electrical stability of the light emitting element LD may be ensured.

Also, in case that the insulative film 14 is provided on the surface of the light emitting element LD, a surface defect of the light emitting element LD may be minimized, thereby improving the lifetime and efficiency of the light emitting element LD. Even in case that multiple light emitting elements LD are densely disposed, an unwanted short circuit may be prevented from occurring between the light emitting elements LD.

In an embodiment, the light emitting element LD may further include an additional component in addition to the first semiconductor layer 11, the active layer 12, the second semiconductor layer 13, and/or the insulative film 14 surrounding the same. For example, the light emitting element LD may include at least one phosphor layer, at least one active layer, at least one semiconductor layer, and/or at least one electrode layer, which are disposed at one ends of the first semiconductor layer 11, the active layer 12, and/or the second semiconductor layer 13. In an embodiment, a contact electrode layer may be disposed at each of the first and second end portions EP1 and EP2 of the light emitting element LD. Although the pillar-shaped light emitting element LD has been illustrated in FIGS. 1 and 2, the kind, structure, and/or shape of the light emitting element LD may be variously changed. For example, the light emitting element LD may be formed in a core-shell structure having a polypyramid shape.

A light emitting device including the above-described light emitting element LD may be used in various kinds of devices which require a light source, including a display device. For example, multiple light emitting elements LD may be disposed in each pixel of a display panel, and may be used as a light source of each pixel. However, the application field of the light emitting element LD is not limited to the above-described example. For example, the light emitting element LD may be used in other types of devices that require a light source, such as a lighting device.

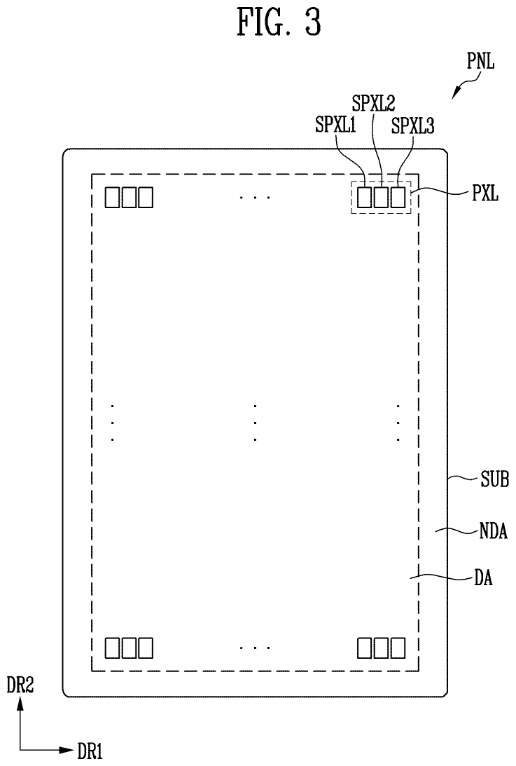

FIG. 3 is a plan view illustrating a display device in accordance with an embodiment of the disclosure. In FIG. 3, a display panel PNL provided in the display device will be illustrated as an example of an electronic device which can use, as a light source, the light emitting element LD described in the embodiment shown in FIGS. 1 and 2.

For convenience of description, in FIG. 3, a structure of the display panel PNL will be briefly illustrated based on a display area DA. However, in some embodiments, at least one driving circuit (e.g., at least one of a scan driver and a data driver), lines, and/or pads, which are not shown, may be disposed in the display panel PNL.

The disclosure may be applied as long as the display device is an electronic device in which a display surface is applied to at least one surface thereof, such as a smartphone, a television, a tablet personal computer (PC), a mobile phone, a video phone, an electronic book reader, a desktop PC, a laptop PC, a netbook computer, a workstation, a server, a personal digital assistant (PDA), a portable multimedia player (PMP), an MP3 player, a medical device, a camera, or a wearable device.

Referring to FIG. 3, the display panel PNL may include a substrate SUB and pixels PXL disposed on the substrate SUB.

The substrate SUB may constitute a base member of the display panel PNL, and may be a rigid or flexible substrate or film. In an embodiment, the substrate SUB may be configured as a rigid substrate made of glass or tempered glass, a flexible substrate (or thin film) made of plastic or metal, or at least one insulating layer. The material and/or property of the substrate SUB is not particularly limited.

In an embodiment, the substrate SUB may be substantially transparent. The term “substantially transparent” may mean that light can be transmitted with a predetermined (or selectable) transmittance or more. In another embodiment, the substrate SUB may be translucent or opaque. In some embodiments, the substrate SUB may include a reflective material.

The display panel PNL and the substrate SUB may include the display area DA for displaying an image and a non-display area NDA other than the display area DA.

The pixels PXL may be arranged in the display area DA. Various lines, pads, and/or a built-in circuit, which are connected to the pixels PXL of the display area DA, may be disposed in the non-display area NDA.

The pixel PXL may include sub-pixels SPXL1 to SPXL3. For example, the pixel PXL may include a first sub-pixel SPXL1, a second sub-pixel SPXL2, and a third sub-pixel SPXL3.

Each of the sub-pixels SPXL1 to SPXL3 may emit light of a predetermined (or selectable) color. In some embodiments, the sub-pixels SPXL1 to SPXL3 may emit lights of different colors. In an embodiment, the first sub-pixel SPXL1 may emit light of a first color, the second sub-pixel SPXL2 may emit light of a second color, and the third sub-pixel SPXL3 may emit light of a third color. For example, the first sub-pixel SPXL1 may be a red pixel emitting light of red, the second sub-pixel SPXL2 may be a green pixel emitting light of green, and the third sub-pixel SPXL3 may be a blue pixel emitting light of blue. However, the disclosure is not limited thereto.

In an embodiment, the first sub-pixel SPXL1, the second sub-pixel SPXL2, and the third sub-pixel SPXL3 may have, as light sources, a light emitting element of the first color, a light emitting element of the second color, and a light emitting element of the third color, to emit lights of the first color, the second color, and the third color, respectively. In another embodiment, the first sub-pixel SPXL1, the second sub-pixel SPXL2, and the third sub-pixel SPXL3 may have light emitting elements emitting light of the same color and include color conversion layers and/or color filters of different colors, which are disposed above the respective light emitting elements, to respectively emit lights of the first color, the second color, and the third color. However, the color, kind, and/or number of sub-pixels SPXL1 to SPXL3 constituting each pixel PXL are not particularly limited. For example, the color of light emitted by each pixel PXL may be variously changed.

The sub-pixels SPXL1 to SPXL3 may be regularly arranged in a stripe structure, a PENTILE™ structure, or the like. For example, the first, second, and third sub-pixels SPXL1, SPXL2, and SPXL3 may be sequentially and repeatedly disposed in a first direction DR1. Also, the first, second, and third sub-pixels SPXL1, SPXL2, and SPXL3 may be repeatedly disposed in a second direction DR2. At least one first sub-pixel SPXL1, at least one second sub-pixel SPXL2, and at least one third sub-pixel SPXL3 may constitute one pixel PXL capable of emitting lights of various colors. However, the arrangement structure of the sub-pixels SPXL1 to SPXL3 is not limited thereto, and the sub-pixels SPXL1 to SPXL3 may be arranged in the display area DA in various structures and/or various patterns.

In an embodiment, each of the sub-pixels SPXL1 to SPXL3 may be configured as an active pixel. For example, each of the sub-pixels SPXL1 to SPXL3 may include at least one light source (e.g., at least one light emitting element) driven by a predetermined (or selectable) control signal (e.g., a scan signal and a data signal) and/or a predetermined (or selectable) power source (e.g., a first power source and a second power source). However, the kind, structure, and/or driving method of the sub-pixels SPXL1 to SPXL3, which can be applied to the display device, are not particularly limited.

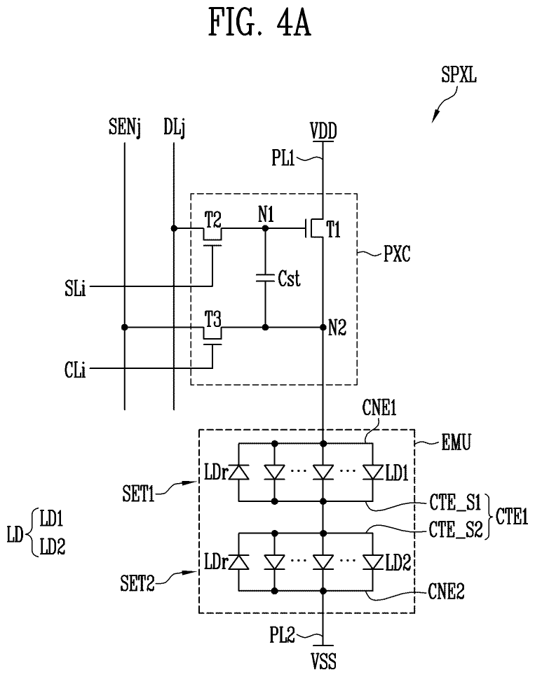

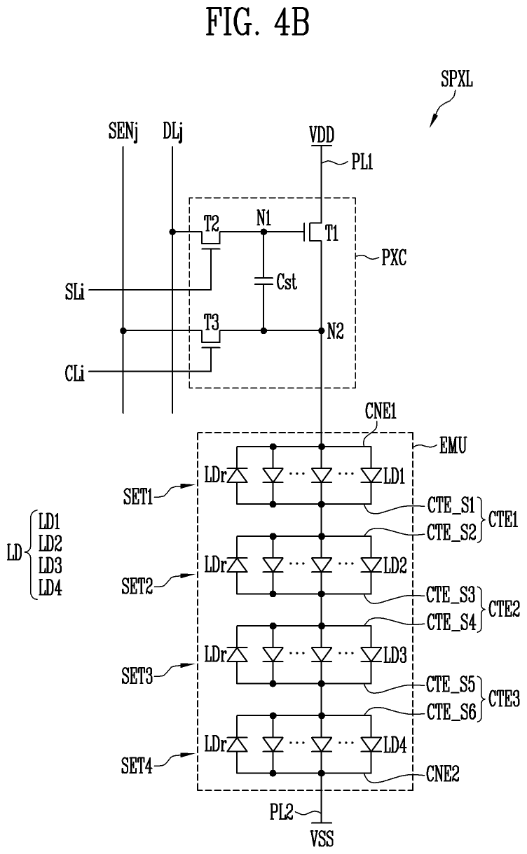

FIGS. 4A and 4B are each a schematic diagram of an equivalent circuit of the sub-pixel in the display device shown in FIG. 3 in accordance with an embodiment of the disclosure.

In the following embodiment, in case that a first sub-pixel SPXL1, a second sub-pixel SPXL2, and a third sub-pixel SPXL3 are inclusively designated, each of the first, second, and third sub-pixels SPXL1, SPXL2, and SPXL3 or the first, second, and third sub-pixels SPXL1, SPXL2, and SPXL3 will be referred to as a “sub-pixel SPXL” or “sub-pixels SPXL.” FIGS. 4A and 4B illustrate an electrical connection relationship of components included in the sub-pixel SPXL applicable to an active matrix type display device. However, the connection relationship of the components of the sub-pixel SPXL is not limited thereto.

Referring to FIGS. 3, 4A, and 4B, the sub-pixel SPXL may include a light emitting unit EMU (or light emitting part) which generates light with a luminance corresponding to a data signal. The sub-pixel SPXL may selectively include a pixel circuit PXC for driving the light emitting unit EMU.

In some embodiments, the light emitting unit EMU may include multiple light emitting elements LD connected in parallel between a first power line PL1 and a second power line PL2. The first power line PL1 may be connected to a first driving power source VDD such that a voltage of the first driving power source VDD is applied thereto, and the second power line PL2 may be connected to a second driving power source VSS such that a voltage of the second driving power source VSS is applied thereto.

For example, the light emitting unit EMU may include a first pixel electrode CNE1 (or contact electrode) connected to the first driving power source VDD via the pixel circuit PXC and the first power line PL1, a second pixel electrode CNE2 (or contact electrode) connected to the second driving power source VSS through the second power line PL2, and multiple light emitting elements LD connected in parallel in the same direction between the first pixel electrode CNE1 and the second pixel electrode CNE2. In an embodiment, the first pixel electrode CNE1 may be an anode, and the second pixel electrode CNE2 may be a cathode.

Each of the light emitting elements LD included in the light emitting unit EMU may include a first end portion connected to the first driving power source VDD through the first pixel electrode CNE1 and a second end portion connected to the second driving power source VSS through the second pixel electrode CNE2. The first driving power source VDD and the second driving power source VSS may have different potentials. In an embodiment, the first driving power source VDD may be a high-potential power source, and the second driving power source VSS may be a low-potential power source. A potential difference between the first and second driving power sources VDD and VSS may be equal to or higher than a threshold voltage of the light emitting elements LD during an emission period of each sub-pixel SPXL.

As described above, the light emitting elements LD connected in parallel in the same direction (e.g., a forward direction) between the first pixel electrode CNE1 and the second pixel electrode CNE2, to which voltages having difference potentials are supplied, may form respective effective light sources.

Each of the light emitting elements LD of the light emitting unit EMU may emit light with a luminance corresponding to a driving current supplied through a corresponding pixel circuit PXC. For example, the pixel circuit PXC may supply, to the light emitting unit EMU, a driving current corresponding to a grayscale value of corresponding frame data during each frame period. The driving current supplied to the light emitting unit EMU may be divided to flow through each of the light emitting elements LD. Accordingly, the light emitting unit EMU may emit light with a luminance corresponding to the driving current while each light emitting element LD emits light with a luminance corresponding to a current flowing therethrough.

Although an embodiment in which both end portions of the light emitting elements LD are connected in the same direction between the first and second driving power sources VDD and VSS has been described, the disclosure is not limited thereto. In some embodiments, the light emitting unit EMU may include at least one ineffective light source, e.g., a reverse light emitting element LDr, in addition to the light emitting elements LD forming the respective effective light sources. The reverse light emitting element LDr may be connected in parallel with other light emitting elements LD forming the effective light sources between the first and the second pixel electrodes CNE1 and CNE2, and may be connected between the first and second pixel electrodes CNE1 and CNE2 in a direction opposite to which the other light emitting elements LD are connected. Even if a driving voltage (e.g., a forward driving voltage) is applied between the first and the second pixel electrodes CNE1 and CNE2, the reverse light emitting element LDr may maintain an inactivated state, and accordingly, no current may substantially flow through the reverse light emitting element LDr.

The pixel circuit PXC of the sub-pixel SPXL may be connected to a scan line SLi and a data line DLj. The pixel circuit PXC of the sub-pixel SPXL may be also connected to a control line CLi and a sensing line SENj. In an embodiment, in case that the sub-pixel SPXL is disposed on an ith row and a jth column of the display area DA, the pixel circuit PXC of the sub-pixel SPXL may be connected an ith scan line SLi, a jth data line DLj, an ith control line CLi, and a jth sensing line SENj of the display area DA.

The pixel circuit PXC may include transistors T1 to T3 and a storage capacitor Cst.

A first transistor T1 may be a driving transistor for controlling a driving current applied to the light emitting unit EMU, and may be connected between the first driving power source VDD and the light emitting unit EMU. For example, a first terminal (or a first transistor electrode) of the first transistor T1 may be electrically connected to the first driving power source VDD through the first power line PL1, a second terminal (or second transistor electrode) of the first transistor T1 may be electrically connected to a second node N2, and a gate electrode of the first transistor T1 may be electrically connected to a first node N1. The first transistor T1 may control an amount of driving current applied to the light emitting unit EMU through the second node N2 from the first driving power source VDD according to a voltage applied to the first node N1. In an embodiment, the first terminal of the first transistor T1 may be a drain electrode, and the second terminal of the first transistor T1 may be a source electrode. However, the disclosure is not limited thereto. In some embodiments, the first terminal may be the source electrode, and the second terminal may be the drain electrode.

A second transistor T2 may be a switching transistor which selects a sub-pixel SPXL in response to a scan signal and activates the sub-pixel SPXL, and may be connected between the data line DLj and the first node N1. A first terminal of the second transistor T2 may be connected to the data line DLj, a second terminal of the second transistor T2 may be connected to the first node N1, and a gate electrode of the second transistor T2 may be connected to the scan line SLi. The first terminal and the second terminal of the second transistor T2 may be different terminals. For example, in case that the first terminal is a drain electrode, the second terminal may be a source electrode.

The second transistor T2 may be turned on in case that a scan signal having a gate-on voltage (e.g., a high level voltage) is supplied from the scan line SLi, to electrically connect the data line DLj and the first node N1 to each other. The first node N1 may be a point at which the second terminal of the second transistor T2 and the gate electrode of the first transistor T1 are connected to each other, and the second transistor T2 may transfer a data signal to the gate electrode of the first transistor T1.

A third transistor T3 may connect the first transistor T1 to the sensing line SENj, so that a sensing signal is acquired through the sensing line SENj. Accordingly, a characteristic of the sub-pixel SPXL, including a threshold voltage of the first transistor T1, and the like, may be detected by using the sensing signal. Information on the characteristic of the sub-pixel SPXL may be used to convert image data such that a characteristic deviation between sub-pixels SPXL can be compensated. A second terminal of the third transistor T3 may be connected to the second terminal of the first transistor T1, a first terminal of the third transistor T3 may be connected to the sensing line SENj, and a gate electrode of the third transistor T3 may be connected to the control line CLi. The first terminal of the third transistor T3 may be connected to an initialization power source. The third transistor T3 may be an initialization transistor capable of initializing the second node N2, and may be turned on in case that a sensing control signal is supplied from the control line CLi, to transfer the voltage of the initialization power source to the second node N2. Accordingly, a second storage electrode of the storage capacitor Cst, which is electrically connected to the second node N2, may be initialized.

The storage capacitor Cst may include a first storage electrode (or lower electrode) and a second storage electrode (or upper electrode). The first storage electrode may be electrically connected to the first node N1, and the second storage electrode may be electrically connected to the second node N2. The storage capacitor Cst may charge a data voltage corresponding to the data signal supplied to the first node N1 during one frame period. Accordingly, the storage capacitor Cst may store a voltage corresponding to the difference between a voltage of the gate electrode of the first transistor T1 and a voltage of the second node N2.

The light emitting unit EMU may include at least one serial stage (or stage) including multiple light emitting elements LD electrically connected in parallel to each other. In an embodiment, the light emitting unit EMU may be configured with a series/parallel hybrid structure as shown in FIGS. 4A and 4B. In an embodiment, as shown in FIG. 4A, the light emitting unit EMU may be configured to include a first serial stage SET1 and a second serial stage SET2. In another example, as shown in FIG. 4B, the light emitting unit EMU may be configured to include four serial stages SET1 to SET4. The number of serial stages included in the light emitting unit EMU may be variously changed. For example, the light emitting unit EMU may include three or five or more serial stages. In another example, the light emitting unit EMU may include only one serial stage.

Referring to FIG. 4A, the light emitting unit EMU may include first and second serial stages SET1 and SET2, which are sequentially connected between the first driving power source VDD and the second driving power source VSS. Each of the first and second serial stages SET1 and SET2 may include two electrodes (CNE1 and CTE_S1 or CTE_S2 and CNE2) constituting an electrode pair of the corresponding serial stage and multiple light emitting elements LD connected in parallel in the same direction between the two electrodes (CNE1 and CTE_S1 or CTE_S2 and CNE2).

The first serial stage SET1 (or first stage) may include a first pixel electrode CNE1 and a first sub-intermediate electrode CTE_S1, and include at least one first light emitting element LD1 connected between the first pixel electrode CNE1 and the first sub-intermediate electrode CTE_S1. The first serial stage SET1 may further include a reverse light emitting element LDr connected in an opposite direction to other first light emitting element LD1 between the first pixel electrode CNE1 and the first sub-intermediate electrode CTE_S1.

The second serial stage SET2 (or second stage) may include a second sub-intermediate electrode CTE_S2 and a second pixel electrode CNE2, and include at least one second light emitting element LD2 connected between the second sub-intermediate electrode CTE_S2 and the second pixel electrode CNE2. The second serial stage SET2 may further include a reverse light emitting element LDr connected in an opposite direction to other second light emitting element LD2 between the second sub-intermediate electrode CTE_S2 and the second pixel electrode CNE2.

The first sub-intermediate electrode CTE_S1 of the first serial stage SET1 and the second sub-intermediate electrode CTE_S2 of the second serial stage SET2 may be integral with each other. In an embodiment, the first sub-intermediate electrode CTE_S1 and the second sub-intermediate electrode CTE_S2 may constitute a first intermediate electrode CTE1 (or contact electrode) for electrically connecting the first serial stage SET1 and the second serial stage SET2, which are consecutive. In case that the first sub-intermediate electrode CTE_S1 and the second sub-intermediate electrode CTE_S2 are integral with each other, the first sub-intermediate electrode CTE_S1 and the second sub-intermediate electrode CTE_S2 may be different portions of the first intermediate electrode CTE1.

In the above-described embodiment, the first pixel electrode CNE1 may be an anode of the light emitting unit EMU, and the second pixel electrode CNE2 may be a cathode of the light emitting unit EMU.

Referring to FIG. 4B, the light emitting unit EMU may include first, second, third, and fourth serial stages SET1, SET2, SET3, and SET4, which are sequentially connected between the first driving power source VDD and the second driving power source VSS. Each of the first, second, third, and fourth serial stages SET1, SET2, SET3, and SET4 may include two contact electrodes (CNE1 and CTE_S1, CTE_S2 and CTE_S3, CTE_S4 and CTE_S5, or CTE_S6 and CNE2) and multiple light emitting elements LD connected in parallel in the same direction between the two contact electrodes (CNE1 and CTE_S1, CTE_S2 and CTE_S3, CTE_S4 and CTE_S5, or CTE_S6 and CNE2).

The first serial stage SET1 shown in FIG. 4B may be substantially identical to the first serial stage SET shown in FIG. 4A.

The second serial stage SET2 (or second stage) shown in FIG. 4B may include a second sub-intermediate electrode CTE_S2 and a third sub-intermediate electrode CTE_S3, and include at least one second light emitting element LD2 electrically connected between the second sub-intermediate electrode CTE_S2 and the third sub-intermediate electrode CTE_S3.

The third serial stage SET3 (or third stage) may include a fourth sub-intermediate electrode CTE_S4 and a fifth sub-intermediate electrode CTE_S5, and include at least one third light emitting element LD3 electrically connected between the fourth sub-intermediate electrode CTE_S4 and the fifth sub-intermediate electrode CTE_S5.

The fourth serial stage SET4 (or fourth stage) may include a sixth sub-intermediate electrode CTE_S6 and a second pixel electrode CNE2, and include at least one fourth light emitting element LD4 electrically connected between the sixth sub-intermediate electrode CTE_S6 and the second pixel electrode CNE2.

The third sub-intermediate electrode CTE_S3 of the second serial stage SET2 and the fourth sub-intermediate electrode CTE_S4 of the second serial stage SET3 may be integral with each other. In case that the third sub-intermediate electrode CTE_S3 and the fourth sub-intermediate electrode CTE_S4 are integral with each other, the third sub-intermediate electrode CTE_S3 and the fourth sub-intermediate electrode CTE_S4 may be different portions of a second intermediate electrode CTE2. Similarly, the fifth sub-intermediate electrode CTE_S5 of the third serial stage SET3 and the sixth sub-intermediate electrode CTE_S6 of the fourth serial stage SET4 may be integral with each other. In case that the fifth sub-intermediate electrode CTE_S5 and the sixth sub-intermediate electrode CTE_S6 are integral with each other, the fifth sub-intermediate electrode CTE_S5 and the sixth sub-intermediate electrode CTE_S6 may be different portions of a third intermediate electrode CTE3.

The light emitting unit EMU of the sub-pixel SPXL, which includes serial stages SET1 to SET4 (or light emitting elements LD) connected in a series/parallel hybrid structure, may readily control driving current/voltage to be suitable for specifications of a product to which the light emitting unit EMU is applied.

For example, the light emitting unit EMU of the sub-pixel SPXL, which includes the serial stages SET1 to SET4 (or the light emitting elements LD) connected in the series/parallel hybrid structure, may decrease a driving current, as compared with a light emitting unit having a structure in which light emitting elements LD are connected only in parallel. Also, the light emitting unit EMU of the sub-pixel SPXL, which includes the serial stages SET1 to SET4 (or the light emitting elements LD) connected in the series/parallel hybrid structure, may decrease a driving voltage applied to both ends of the light emitting unit EMU, as compared with a light emitting unit having a structure in which the same number of light emitting elements LD are connected only in series. Further, the light emitting unit EMU of the sub-pixel SPXL, which includes the serial stages SET1 to SET4 (or the light emitting elements LD) connected in the series/parallel hybrid structure, may include a larger number of light emitting elements LD between the same number of contact electrodes CNE1, CTE1, CTE2, CTE3, and CNE2, as compared with a light emitting unit having a structure in which serial stages (or stages) are all connected in series. Thus, the light emission efficiency of light emitting elements LD may be improved. Even if a defect occurs in a specific serial stage (or stage), the ratio of light emitting element LD which do not emit light due to the defect may be relatively decreased. Accordingly, deterioration of the light emission efficiency of light emitting elements LD may be reduced.

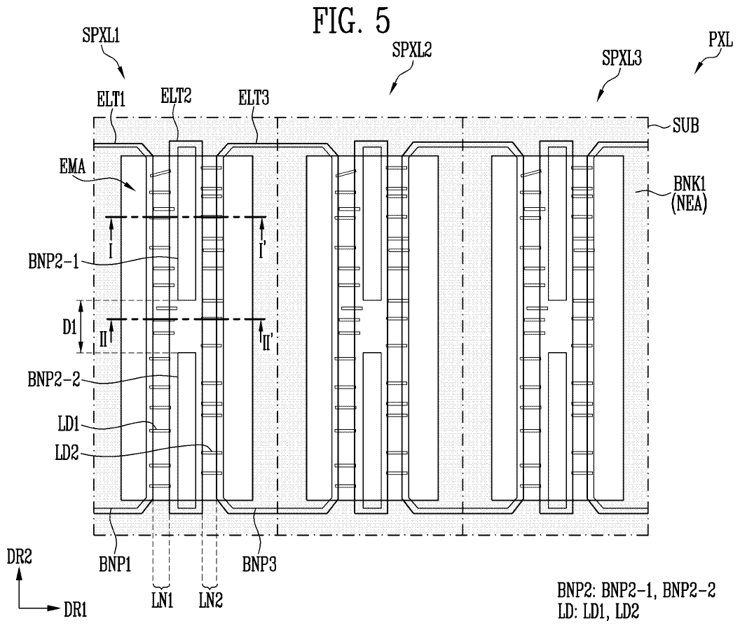

FIG. 5 is a plan view illustrating an embodiment of the pixel included in the display device shown in FIG. 3. In FIG. 5, a pixel PXL is briefly illustrated based on a light emitting unit EMU (see FIGS. 4A and 4B). Sub-pixels SPXL1 to SPXL3 in the pixel PXL may have light emitting units EMU substantially identical to one another. Therefore, common components of the sub-pixels SPXL1 to SPXL3 are described based on a first sub-pixel SPXL1, and overlapping descriptions will not be repeated.

Referring to FIGS. 3 and 5, the first sub-pixel SPXL1 may be formed in a sub-pixel area (or pixel area) provided in the substrate SUB. The sub-pixel area (or the first sub-pixel SPXL1) may include an emission area EMA and a non-emission area NEA other than the emission area EMA. The non-emission area NEA may be an area disposed adjacent to the emission area EMA.

The first sub-pixel SPXL1 may include a first bank BNK1, electrodes ELT1 to ELT3 (alignment electrodes, or reflective electrodes), bank patterns BNP1 to BNP3, and a light emitting element LD. The electrodes ELT1 to ELT3 may include a first electrode ELT1, a second electrode ELT2, and a third electrode ELT3, but the disclosure is not limited thereto. The third electrode ELT3 may be a first electrode ELT1 of an adjacent sub-pixel (e.g., a second sub-pixel SPXL2).

The first bank BNK1 may be located in the non-emission area NEA. The first bank BNK1 may be a structure defining (or partitioning) an emission area EMA of each sub-pixel between the sub-pixels SPXL1 to SPXL3. The first bank BNK1 may be a pixel defining layer or a dam structure, which defines an area to which light emitting elements LD are to be supplied in a process of supplying the light emitting elements LD to each of the sub-pixels SPXL1 to SPXL3. In an embodiment, an emission area EMA of each of the sub-pixels SPXL1 to SPXL3 may be partitioned by the first bank BNK1, so that a mixed liquid (e.g., ink) including a desired amount and/or a desired kind of light emitting element LD can be supplied (or input) to the emission area EMA. The first bank BNK1 may have liquid repellant.

Each of the electrodes ELT1 to ELT3 may extend in the second direction DR2, and the electrodes ELT1 to ELT3 may be spaced apart from each other along the first direction DR1. A portion of each of the electrodes ELT1 to ELT3, which extends in the second direction DR2, may overlap the first bank BNK1, but the disclosure is not limited thereto. For example, at least one of the electrodes ELT1 to ELT3 may not overlap the first bank BNK1.

The electrodes ELT1 to ELT3 of the first sub-pixel SPXL1 may be respectively separated from electrodes ELT1 to ELT3 included in a sub-pixel adjacent to the first sub-pixel SPXL1 in the second direction DR2, but the disclosure is not limited thereto. For example, at least one of the electrodes ELT1 to ELT3 of the first sub-pixel SPXL1 may be connected to an electrode included in the sub-pixel adjacent to the first sub-pixel SPXL1 in the second direction DR2.

The second electrode ELT2 may be located to be spaced apart from the first electrode ELT1 in the first direction DR1. The third electrode ELT3 may be located to be spaced apart from the second electrode ELT2 in the first direction DR1.

The electrodes ELT1 to ELT3 may be used as alignment electrodes by applying an alignment voltage after inputting a mixed liquid (e.g., an ink) including the light emitting element LD to the emission area EA. The first electrode ELT1 may be a first alignment electrode, the second electrode ELT2 may be a second alignment electrode, and the third electrode ELT3 may be a third alignment electrode. A first light emitting element LD1 may be aligned in a desired direction and/or at a desired position by an electric field formed between the first alignment electrode and the second alignment electrode. Similarly, a second light emitting element LD2 may be aligned in a desired direction and/or at a desired position by an electric field formed between the second alignment electrode and the third alignment electrode. In some embodiments, the electrodes ELT1 to ELT3 may be used as driving electrodes for driving light emitting elements LD after the light emitting elements LD are aligned. One of the electrodes ELT1 to ELT3 may constitute the anode of the light emitting unit EMU, and another one of the electrodes ELT1 to ELT3 may constitute the cathode of the light emitting unit EMU. For example, the first electrode ELT1 may constitute the anode of the light emitting unit EMU, and be connected to the first transistor T1 shown in FIG. 4A through a contact hole or the like. For example, the second electrode ELT2 may constitute the cathode of the light emitting unit EMU, and be connected to the second power line PL2 shown in FIG. 4A through a contact hole or the like.

The electrodes ELT1 to ELT3 may have a bar shape extending along the second direction DR2 in a plan view, but the disclosure is not limited thereto. The shape of the electrodes ELT1 to ELT3 may be variously changed.

The bank patterns BNP1 to BNP3 may be located corresponding to the electrodes ELT1 to ELT3. For example, a first bank pattern BNP1 may overlap the first electrode ELT1 in a plan view, a second bank pattern BNP2 may overlap the second electrode ELT2 in a plan view, and a third bank pattern BNP3 may overlap the third electrode ELT3 in a plan view. The bank patterns BNP1 to BNP3 may extend along the second direction DR2, corresponding to the electrodes ELT1 to ELT3. At least some of the bank patterns BNP1 to BNP3 may extend across the emission area EMA.

The bank patterns BNP1 to BNP3 may form a step so as to readily align light emitting elements in the emission area EMA. Also, the bank patterns BNP1 to BNP3 may support members which support the electrodes ELT1 to ELT3 to change a surface profile (or shape) of the electrodes ELT1 to ELT3 such that light emitted from the light emitting elements LD is guided in an image display direction of the display device (e.g., a third direction DR3). The second bank pattern BNP2 may be located between the first bank pattern BNP1 and the third bank pattern BNP3, and divide one emission area EMA into two sub-emission areas in the first direction DR1 or partition a first path LN1 and a second path LN2, in which light emitting elements LD are arranged in one emission area EMA.

In embodiments, the second bank pattern BNP2 may include sub-patterns (or sub-bank patterns), each of which extends in the second direction DR2, and which are spaced apart from each other in the second direction DR2. In other words, the second bank pattern BNP2 may be discontinuously disposed along the second direction DR2 in the emission area EMA, and include at least one discontinuous area along the second direction DR2 (or along an extending direction of the second bank pattern BNP2).

In an embodiment, the second bank pattern BNP2 may include a first sub-pattern BNP2-1 and a second sub-pattern BNP2-2. With respect to the center area of the emission area EMA, the first sub-pattern BNP2-1 may be located in an upper area of the emission area EMA in a plan view, and the second sub-pattern BNP2-2 may be located in a lower area of the emission area EMA in a plan view.

The first sub-pattern BNP2-1 and the second sub-pattern BNP2-2 may be spaced apart from each other with a first distance D1 in the second direction DR2. One ends of the first sub-pattern BNP2-1 and the second sub-pattern BNP2-2 may be spaced apart from each other at the center of the emission area EMA, and another ends of the first and second sub-patterns BNP2-1 and BNP2-2 (e.g., an uppermost portion and a lowermost portion of the second bank pattern BNP2) may overlap the first bank BNK1. However, the disclosure is not limited thereto. For example, the discontinuous area of the second bank BNK2 may not be disposed at the center area of the emission area EMA.

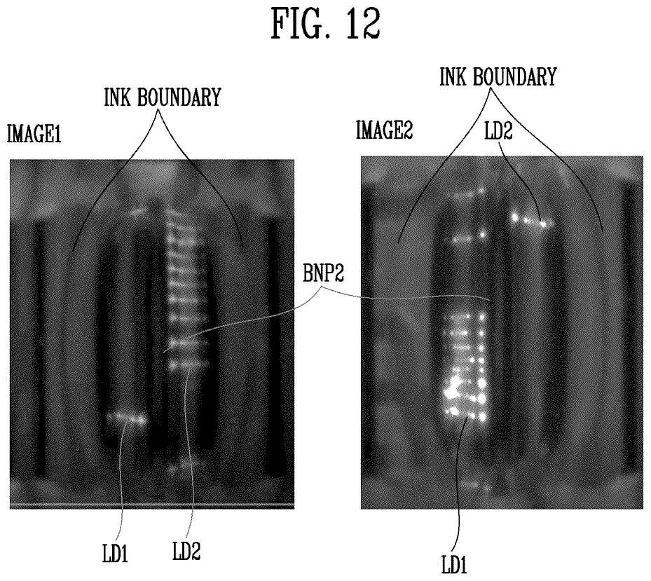

Although will be described later with reference to FIG. 12, in a manufacturing process, a mixed liquid (e.g., an ink) including light emitting elements LD may be input to the emission area EMA, and the light emitting elements LD may be moved and aligned according to an electric filed formed between the electrodes ELT1 to ELT3. A space (or moving path) between the first sub-pattern BNP2-1 and the second sub-pattern BNP2-2 may allow the light emitting elements LD to be moved between the first path LN1 and the second path LN2, and allow a uniform number of light emitting elements LD to be arranged in the first path LN1 and the second path LN2.

In an embodiment, the first distance D1 between the first sub-pattern BNP2-1 and the second sub-pattern BNP2-2 may be about two times to about five times of the length L (see FIG. 1) of the light emitting element LD. For example, in case that the length L of the light emitting element LD is about 3.5 μm to about 5 μm, the distance D1 may be about 10 μm to about 20 μm. In case that a length of the emission area EMA in the second direction DR2 is about 100 μm, the first distance D1 may be about 10% to about 20% of the length of the emission area EMA, but the disclosure is not limited thereto. In case that the first distance D1 is smaller than two times of the length L of the light emitting element LD, the movement of the light emitting element LD between the first path LN1 and the second path LN2 may be difficult. In case that the first distance D1 is greater than five times of the length L of the light emitting element LD, the second bank pattern BNP2 may not have any corresponding function (i.e., a function of forming a step and changing a surface profile of the second electrode ELT2), and the light emission efficiency of the first sub-pixel SPXL1 may be lowered.

The second electrode ELT2 may continuously extend from the first sub-pattern BNP2-1 to the second sub-pattern BNP2-2 through the area (or discontinuous area) between the first sub-pattern BNP2-1 and the second sub-pattern BNP2-2. However, the disclosure is not limited thereto. For example, similarly to the second bank pattern BNP2, the second electrode ELT2 may also be discontinuously disposed.

Light emitting elements LD may be disposed between adjacent electrodes among the electrodes ELT1 to ELT3 such that the length L (see FIG. 1) direction of each of the light emitting elements LD is substantially parallel to the first direction DR1. For example, the first light emitting element LD1 may be disposed between the first electrode ELT1 and the second electrode ELT2, and the second light emitting element LD2 may be disposed between the second electrode ELT2 and the third electrode ELT3.

As described above, the first sub-pixel SPXL1 may include the bank patterns BNP1 to BNP3 for change the surface profile of the electrodes ELT1 to ELT3, and the second bank pattern BNP2 defining or partitioning the first and second paths LN1 and LN2 in which the light emitting elements LD are arranged may include the first and second sub-patterns BNP2-1 and BNP2-2 separated or spaced apart from each other along the extending direction (e.g., the second direction DR2). In a manufacturing process of the display device, the movement of light emitting elements LD between the first and second paths LN1 and LN2 may be allowed through the space between the first and second sub-patterns BNP2-1 and BNP2-2, and hence the number of light emitting elements LD aligned in the first and second paths LN1 and LN2 may become uniform. Thus, a luminance variation between the first and second paths LN1 and LN2 and a luminance variation between pixels PXL may be reduced or decreased.

Although a case where the second bank pattern BNP2 includes two sub-patterns (i.e., the first and second sub-patterns BNP2-1 and BNP2-2) has been illustrated in FIG. 5, the number of sub-patterns (and separation spaces between the sub-patterns) is not limited thereto. For example, the number of sub-patterns (and separation spaces between the sub-patterns) may be variously changed according to a size (i.e., an area and a length) of the emission area EML, a number of paths, and the like.

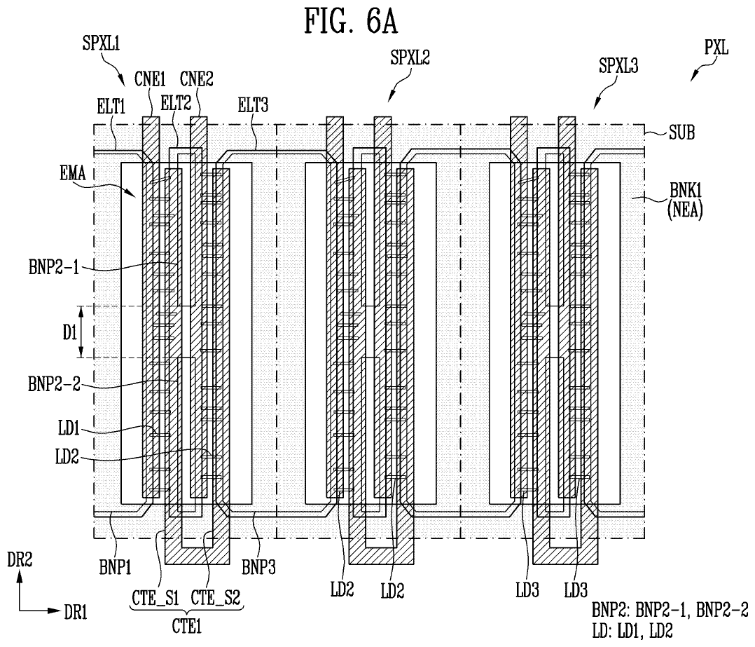

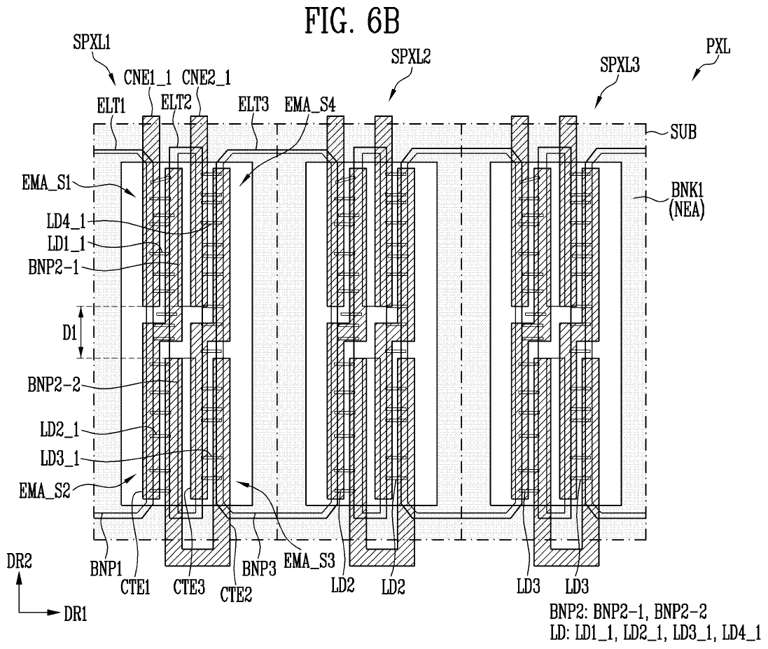

FIG. 6A is a plan view illustrating an embodiment of the pixel shown in FIG. 5.

Referring to FIGS. 5 and 6A, the first sub-pixel SPXL1 may include a first pixel electrode CNE1, a first intermediate electrode CTE1, and a second pixel electrode CNE2. The first sub-pixel SPXL1 may have the pixel structure (or two serial stages) shown in FIG. 4A. The terms “pixel electrode” and “intermediate electrode” are used to be distinguished from an electrode (or alignment electrode), and the corresponding component (i.e., the electrode) is not limited by the terms.

The first pixel electrode CNE1 may be located to overlap the first end portion of the first light emitting element LD1 and the first electrode ELT1. The first pixel electrode CNE1 may extend in the second direction DR2, corresponding to the first electrode ELT1. The first pixel electrode CNE1 may be connected to the first end portion of the first light emitting element LD1. The first pixel electrode CNE1 may constitute the anode of the light emitting unit EMU (see FIG. 4A), and be connected to the first transistor T1 shown in FIG. 4A through a contact hole or the like. The first pixel electrode CNE1 may be electrically separated or electrically insulated from the first electrode ELT1. However, the disclosure is not limited thereto. For example, the first pixel electrode CNE1 may be electrically connected to the first electrode ELT1.

The first intermediate electrode CTE1 may overlap the second end portion of the light emitting element LD1 and the second electrode ELT2. Also, the first intermediate electrode CTE1 may overlap the first end portion of the second light emitting element LD2 and the third electrode ELT3. The first intermediate electrode CTE1 may physically and/or electrically connect the second end portion of the first light emitting element LD1 and the first end portion of the second light emitting element LD2 to each other.

For example, a first sub-intermediate electrode CTE_S1 of the first intermediate electrode CTE1 may overlap the second end portion of the first light emitting element LD1 and the second electrode ELT2, and a second sub-intermediate electrode CTE_S2 of the first intermediate electrode CTE1 may overlap the first end portion of the second light emitting element LD2 and the third electrode ELT3. The first intermediate electrode CTE1 may extend in a form in which the first intermediate electrode CTE1 bypasses the second pixel electrode CNE2. The first sub-intermediate electrode CTE_S1 may extend in the second direction DR2, corresponding to the second electrode ELT2, and the second sub-intermediate electrode CTE_S2 may extend in the second direction DR2, corresponding to the third electrode ELT3. The first intermediate electrode CTE1 may be disposed even in an area between the first and second sub-patterns BNP2-1 and BN P2-2.

The second pixel electrode CNE2 may be located to overlap the second end portion of the second light emitting element LD2 and the second electrode ELT2. The second pixel electrode CNE2 may extend in the second direction DR2, corresponding to the second electrode ELT2. The second pixel electrode CNE2 may be disposed even in an area between the first and second sub-patterns BNP2-1 and BNP2-2. The second pixel electrode CNE2 may be connected to the second end portion of the second light emitting element LD2. The second pixel electrode CNE2 may constitute the cathode of the light emitting unit EMU (see FIG. 4A), and be connected to the second power line PL2 shown in FIG. 4A through a contact hole or the like. The second pixel electrode CNE2 may be electrically separated or electrically insulated from the second electrode ELT2. However, the disclosure is not limited thereto. For example, the second pixel electrode CNE2 may be electrically connected to the second electrode ELT2.

The first pixel electrode CNE1, the second pixel electrode CNE2, the first sub-intermediate electrode CTE_S1 of the first intermediate electrode CTE1, and the second sub-intermediate electrode CTE_S2 of the first intermediate electrode CTE1 may have a bar shape extending along the second direction DR2 in a plan view, but the disclosure is not limited thereto. In some embodiments, the shape of the first pixel electrode CNE1, the second pixel electrode CNE2, and the first intermediate electrode CTE1 may be variously changed within a range in which the first pixel electrode CNE1, the second pixel electrode CNE2, and the first intermediate electrode CTE1 are stably electrically connected to each of the light emitting elements LD. For example, the shape of the first pixel electrode CNE1, the second pixel electrode CNE2, and the first intermediate electrode CTE1 may be changed according to shapes of the electrodes ELT1 to ELT3 and/or a pixel structure (or series/parallel hybrid structure, e.g., a number of serial stages included in the first sub-pixel SPXL1).

FIG. 6B is a plan view illustrating another embodiment of the pixel shown in FIG. 5.

Referring to FIGS. 5, 6A, and 6B, except first and second pixel electrodes CNE1_1 and CNE2_1 and intermediate electrodes CTE1 to CTE3, sub-pixels SPXL1 to SPXL3 shown in FIG. 6B may be substantially identical or similar to the sub-pixels SPXL1 to SPXL3 shown in FIG. 6, respectively. Therefore, overlapping descriptions will not be repeated.

The first sub-pixel SPXL1 may include a first pixel electrode CNE1_1, a first intermediate electrode CTE1, a second intermediate electrode CTE2, a third intermediate electrode CTE3, and a second pixel electrode CNE2_1. The first sub-pixel SPXL1 may include four serial stages.

The first pixel electrode CNE1_1 (or first contact electrode) may be located in a first sub-emission area EMA_S1 to overlap a first end portion of a first light emitting element LD1_1 and the first electrode ELT1.

The first intermediate electrode CTE1 (or second contact electrode) may be located in the first sub-emission area EMA_S1 to overlap a second end portion of the first light emitting element LD1_1 and the second electrode ELT2. Also, the first intermediate electrode CTE1 may be located in a second sub-emission area EMA_S2 to overlap a first end portion of a second light emitting element LD2_1 and the first electrode ELT1. To this end, a portion of the first intermediate electrode CTE1 may have a bent shape between the first and second sub-emission areas EMA_S1 and EMA_S2. The first intermediate electrode CTE1 may be disposed even in an area between the first and second sub-patterns BNP2-1 and BNP2-2, and have a bent shape in the area. The first intermediate electrode CTE1 may physically and/or electrically connect the second end portion of the first light emitting element LD1_1 and the first end portion of the second light emitting element LD2_1 to each other.

The second intermediate electrode CTE2 may be located in the second sub-emission area EMA_S2 to overlap a second end portion of the second light emitting element LD2_1 and the second electrode ELT2. Also, the second intermediate electrode CTE2 may be located in a third sub-emission area EMA_S3 to overlap a first end portion of a third light emitting element LD3_1 and the third electrode ELT3. The second intermediate electrode CTE2 may have a shape bypassing the third intermediate electrode CTE3. The second intermediate electrode CTE2 may physically and/or electrically connect the second end portion of the second light emitting element LD2_1 and the first end portion of the third light emitting element LD3_1 to each other.

The third intermediate electrode CTE3 may be located in the third sub-emission area EMA_S3 to overlap a second end portion of the third light emitting element LD3_1 and the second electrode ELt2. Also, the third intermediate electrode CTE3 may be located in a fourth sub-emission area EMA_S4 to overlap a first end portion of a fourth light emitting element LD4_1 and the third electrode ELT3. To this end, a portion of the third intermediate electrode CTE3 may have a shape bent between the third and fourth sub-emission areas EMA_S3 and EMA_S4. The third intermediate electrode CTE3 may be disposed even in an area between the first and second sub-patterns BNP2-1 and BNP2-2, and have a bent shape in the area. The third intermediate electrode CTE3 may physically and/or electrically connect the second end portion of the third light emitting element LD3_1 and the first end portion of the fourth light emitting element LD4_1 to each other.

The second pixel electrode CNE2_1 may be located in the fourth sub-emission area EMA_S4 to overlap a second end portion of the fourth light emitting element LD4_1 and the second electrode ELT2.

The first, second, third, and fourth light emitting elements LD1_1, LD2_1, LD3_1, and LD4_1 may be connected in series to each other between the first and second pixel electrodes CNE_1 and CNE_2 through the intermediate electrodes CTE1 to CTE3. The first light emitting element LD1_1 may constitute a first serial stage, the second light emitting element LD2_1 may constitute a second serial stage, the third light emitting element LD3_1 may constitute a third serial stage, and the fourth light emitting element LD4_1 may constitute a fourth serial stage.

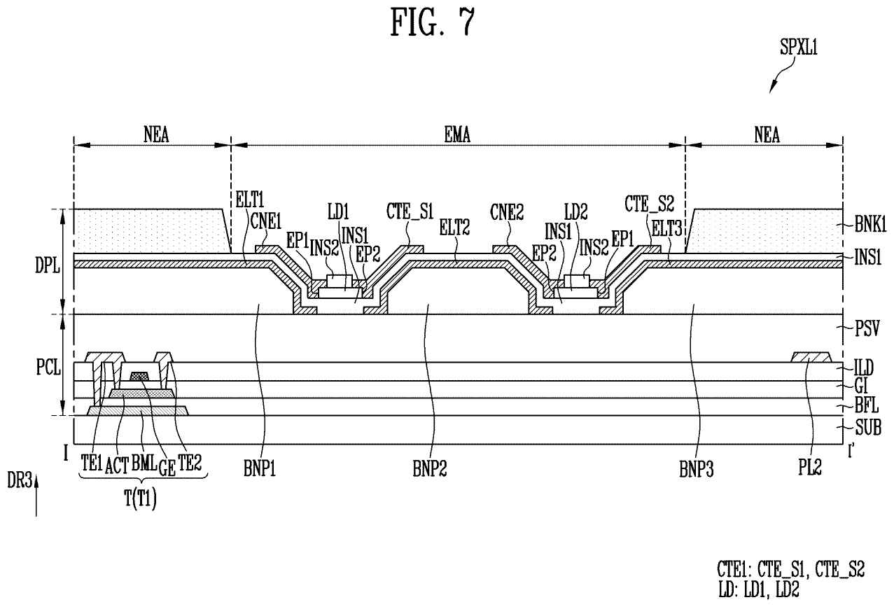

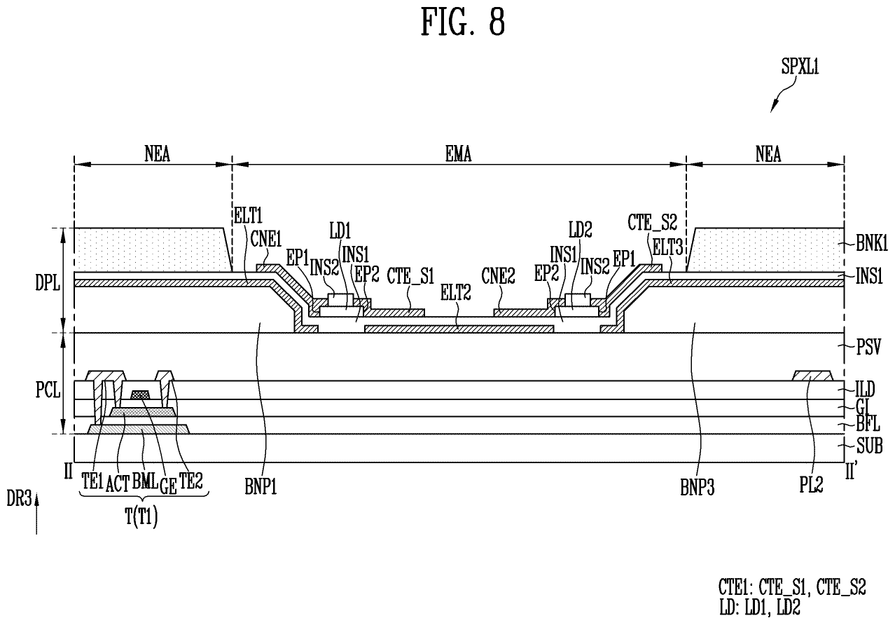

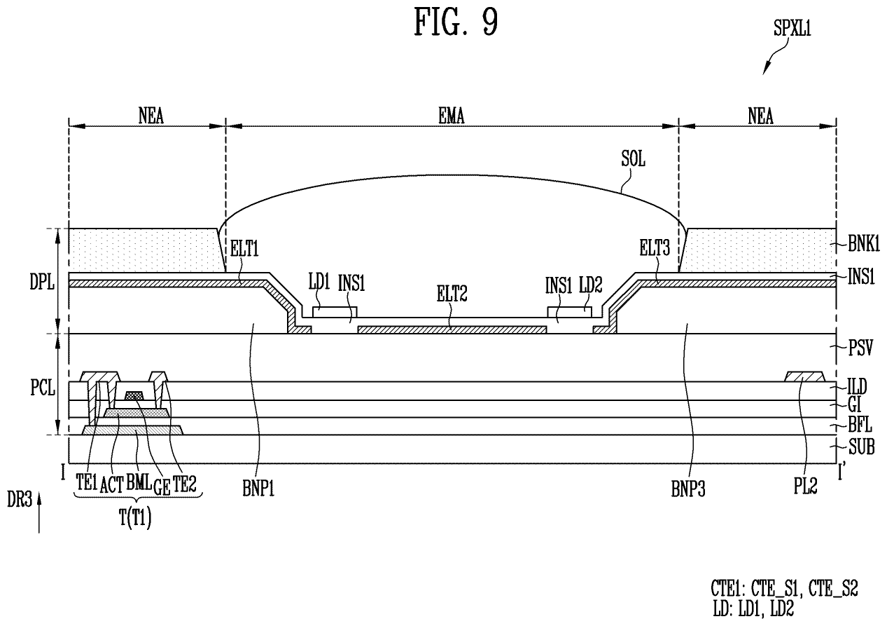

FIG. 7 is a schematic cross-sectional view illustrating an embodiment of the first sub-pixel taken along line I-I′ shown in FIG. 5. FIG. 8 is a schematic cross-sectional view illustrating an embodiment of the first sub-pixel taken along line II-II′ shown in FIG. 5. FIG. 9 is a schematic cross-sectional view illustrating a manufacturing process of the first sub-pixel shown in FIG. 8.

In FIGS. 7 to 9, a first sub-pixel SPXL1 (or sub-pixel) is simplified and illustrated such that each electrode is illustrated only as a single-film electrode and that each insulating layer is illustrated only as a single-film insulating layer. However, the disclosure is not limited thereto.

Referring to FIGS. 5 to 9, the first sub-pixel SPXL1 may include a pixel circuit layer PCL and a display element layer DPL, which are disposed on a substrate SUB.

The substrate SUB may constitute a base member, and may be a rigid or flexible substrate or film. In an embodiment, the substrate SUB may be configured as a rigid substrate made of glass or tempered glass, a flexible substrate (or thin film) made of plastic or metal, or at least one insulating layer. The material and/or property of the substrate SUB is not particularly limited. In an embodiment, the substrate SUB may be substantially transparent. The term “substantially transparent” may mean that light can be transmitted with a predetermined (or selectable) transmittance or more. In another embodiment, the substrate SUB may be translucent or opaque. In another embodiment, the substrate SUB may include a reflective material.

The pixel circuit layer PCL may include a first transistor T1 and a second power line PL2. Also, the pixel circuit layer PCL may include multiple insulating layers BFL, GI, ILD, and PSV. The first transistor T1 may include a lower conductive layer BML, a semiconductor pattern ACT, a gate electrode GE, and first and second transistor electrodes TE1 and TE2.

The lower conductive layer BML may be disposed on the substrate SUB. The lower conductive layer BML may overlap the semiconductor pattern ACT of the first transistor T1, and constitute a back-gate electrode of the first transistor T1.

The lower conductive layer BML may include a conductive material. For example, the conductive material may include molybdenum (Mo), copper (Cu), aluminum (Al), chromium (Cr), gold (Au), titanium (Ti), nickel (Ni), neodymium (Nd), indium (In), tin (Sn), and oxides or alloys thereof. The lower conductive layer BML may be formed as a single layer or a multi-layer.

A buffer layer BFL may be disposed over the lower conductive layer BML. The buffer layer BFL may prevent an impurity from being diffused into a circuit element. The buffer layer BFL may be configured as a single layer. In another embodiment, the buffer layer BFL may be configured as a multi-layer including at least two layers. In case that the buffer layer BFL is formed as a multi-layer, the layers may be formed of a same material or be formed of different materials.

The semiconductor pattern ACT may be disposed on the buffer layer BFL. In an embodiment, the semiconductor pattern ACT may include a first region in contact with the first transistor electrode TE1, a second region in contact with the second transistor electrode TE2, and a channel region located between the first region and the second region. In some embodiments, one of the first and second regions may be a source region, and another one of the first and second regions may be a drain region.

In some embodiments, the semiconductor pattern may be made of poly-silicon, amorphous silicon, an oxide semiconductor, or the like. The channel region of the semiconductor pattern ACT may be a semiconductor pattern undoped with any impurity, and may be an intrinsic semiconductor. Each of the first and second regions of the semiconductor pattern ACT may be a semiconductor doped with an impurity.

A gate insulating layer GI may be disposed on the buffer layer BFL and the semiconductor pattern ACT. In an embodiment, the gate insulating layer GI may be disposed between the semiconductor pattern ACT and the gate electrode GE. The gate insulating layer GI may include an inorganic material. For example, the inorganic material may include silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), titanium oxide (TiOₓ), or a combination thereof. The gate insulating layer GI may be configured with a single layer or a multi-layer.

The gate electrode GE of the first transistor T1 may be disposed on the gate insulating layer GI. The gate electrode GE may overlap the semiconductor pattern ACT in the third direction DR3. The gate electrode GE may include a conductive material, and be formed as a single layer or a multi-layer. For example, the gate electrode GE may be formed as a multi-layer in which titanium (Ti), copper (Cu), and/or indium tin oxide (ITO) are sequentially or repeatedly stacked.

An interlayer insulating layer ILD may be disposed over the gate electrode GE. In an embodiment, the interlayer insulating layer ILD may be disposed between the gate electrode GE and the first and second transistor electrodes TE1 and TE2. The interlayer insulating layer ILD may include an inorganic material, and be configured as a single layer or a multi-layer.

The first and second transistor electrodes TE1 and ET2 of the first transistor T1 and the second power line PL2 may be disposed on the interlayer insulating layer ILD. The first and second transistor electrodes TE1 and ET2 and the second power line PL2 may be disposed in the same layer. For example, the first and second transistor electrodes TE1 and ET2 and the second power line PL2 may be simultaneously formed through a same process, but the disclosure is not necessarily limited thereto.

The first and second transistor electrodes TE1 and ET2 may overlap the semiconductor pattern ACT in the third direction DR3. The first and second transistor electrodes TE1 and ET2 may be electrically connected to the semiconductor pattern ACT. For example, the first transistor electrode TE1 may be electrically connected to the first region of the semiconductor pattern ACT through a contact hole penetrating the interlayer insulating layer ILD. Also, the first transistor electrode TE1 may be electrically connected to the lower conductive layer BML through a contact hole penetrating the interlayer insulating layer ILD and the buffer layer BFL. The second transistor electrode TE2 may be electrically connected to the second region of the semiconductor pattern ACT through a contact hole penetrating the interlayer insulating layer ILD. In some embodiments, one of the first and second transistor electrodes TE1 and TE2 may be a source electrode, and another one of the first and second transistor electrodes TE1 and TE2 may be a drain electrode.

The second power line PL2 may constitute the second power line PL2 described with reference to FIG. 4A.

The first and second transistor electrodes TE1 and TE2 and the second power line PL2 may include a conductive material, and be formed as a single layer or a multi-layer.

A protective layer PSV (or via layer) may be disposed over the first and second transistor electrodes TE1 and TE2 and the second power line PL2.

The protective layer PSV may be made of an organic material and planarize a step difference. For example, the organic material may include an organic material such as an acrylic resin, an epoxy resin, a phenolic resin, a polyamides resin, a polyimides resin, a polyester resin, a poly-phenylene sulfide resin, and benzocyclobutene (BCB). However, the disclosure is not necessarily limited thereto, and the protective layer PSV may include an inorganic material. In another example, an insulating layer including an inorganic material may be disposed between the protective layer PSV including the organic material and the first and second transistor electrode TE1 and TE2.

The display element layer DPL may be disposed on the protective layer PSV. The display element layer DPL may include bank patterns BNP1 to BNP3, electrodes ELT1 to ELT3, a first insulating layer INS1, a light emitting element LD, a second insulating layer INS2 (or second insulating pattern), first and second pixel electrodes CNE1 and CNE2, and a first intermediate electrode CTE1.

The bank patterns BNP1 to BNP3 may be disposed on the protective layer PSV. The bank patterns BNP1 to BNP3 may include at least one organic material and/or at least one inorganic material. The bank patterns BNP1 to BNP3 may have a thickness of a few μm in the third direction DR3.

The bank patterns BNP1 to BNP3 may have various shapes. In an embodiment, the bank patterns BNP1 to BNP3 may have a shape protruding in the third direction DR3 from the substrate SUB. Also, the bank patterns BNP1 to BNP3 may be formed to have an inclined surface inclined at a predetermined (or selectable) angle with respect to the substrate SUB. However, the disclosure is not necessarily limited thereto, and the bank patterns BNP1 to BNP3 may have a sidewall with a curved shape, a stepped shape, or the like. In an embodiment, the bank patterns BNP1 to BNP3 may have a semicircular shape, a semi-elliptical shape, or the like in a cross-sectional view.

The electrodes ELT1 to ELT3 may be disposed on the protective layer PSV and the bank patterns BNP1 to BNP3. For example, a first electrode ELT1 may be disposed over a first bank pattern BNP1, a second electrode may be disposed over a second bank pattern BNP2, and a third electrode ELT3 may be disposed over a third bank pattern BNP3.

The electrodes ELT1 to ELT3 may at least partially cover side surfaces and/or top surfaces of the bank patterns BNP1 to BNP3. The electrodes ELT1 to ELT3 disposed on top of the bank patterns BNP1 to BNP3 may have shapes corresponding to the bank patterns BNP1 to BNP3. In an embodiment, the electrodes ELT1 to ELT3 disposed over the bank patterns BNP1 to BNP3 may include inclined surfaces or curved surfaces, which have shapes corresponding to the shapes of the bank patterns BNP1 to BNP3. The bank patterns BNP1 to BNP3 and the electrodes ELT1 to ELT3 constitute a reflective member, and may reflect light emitted from light emitting elements LD and guide the reflected light in a front direction of the first sub-pixel SPXL1, i.e., in the third direction DR3, thereby improving the light emission efficiency of the display device.

As shown in FIG. 8, the second electrode ELT2 may be disposed in an area in which the second bank pattern BNP2 is not disposed (i.e., an area between first and second sub-patterns BNP2-1 and BNP2-2).

The electrodes ELT1 to ELT3 may include at least one conductive material. In an embodiment, the electrodes ELT1 to ELT3 may include at least one metal or any alloy including the same among various metallic materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), and the like, at least one conductive oxide such as Indium Tin Oxide (ITO), Indium Zinc Oxide (IZO), Indium Tin Zinc Oxide (ITZO), Zinc Oxide (ZnO), Aluminum doped Zinc Oxide (AZO), Gallium doped Zinc Oxide (GZO), Zinc Tin Oxide (ZTO), Gallium Tin Oxide (GTO), and Fluorine doped Tin Oxide (FTO), and at least one conductive material among conductive polymers such as poly(3,4-ethylenedioxythiophene) (PEDOT), but the disclosure is not necessarily limited thereto.

The first insulating layer INS1 may be disposed over the electrodes ELT1 to ELT3. The first insulating layer INS1 may include an inorganic material, and be configured as a single layer or a multi-layer. The insulating layer INS1 may have a thickness of a few tens of nm to a few hundreds of nm in the third direction DR3.

A first bank BNK1 may be disposed on the first insulating layer INS1. The first bank BNK1 may include an opening overlapping an emission area EMA. The opening of the first bank BNK1 may provide a space in which light emitting elements LD can be provided in a process of supplying the light emitting elements LD to the first sub-pixel SPXL1. For example, a desired kind and/or a desired amount of ink (e.g., a mixed liquid including the light emitting elements LD) may be supplied to the space partitioned by the opening of the first bank BNK1.

The first bank BNK1 may include an organic material. However, the disclosure is not necessarily limited thereto, and the first bank BNK1 may include an inorganic material.

Light emitting elements LD may be disposed on the first insulating layer INS1. The light emitting elements LD may be provided in the opening of the first bank BNK1 to be disposed between the bank patterns BNP1 to BNP3 and/or between the electrodes ELT1 to ELT3. In some embodiments, the light emitting elements LD may partially overlap the electrodes ELT1 to ELT3 in the third direction DR3.

The light emitting elements LD may be prepared in a form in which the light emitting elements LD are dispersed in an ink, to be supplied to the first sub-pixel SPXL1 through an inkjet printing process, or the like. In an embodiment, as shown in FIG. 9, the light emitting elements LD may be dispersed in a volatile solvent to be provided to the first sub-pixel SPXL1. Subsequently, in case that an alignment signal is supplied to the electrodes ELT1 to ELT3 as described above, the light emitting elements LD may be aligned between the electrodes ELT1 to ELT3, while an electric field is formed between the electrodes ELT1 to ELT3. As described above with reference to FIG. 5, since any step does not exist between the first and second sub-patterns BNP2-1 and BNP2-2 of the second bank BNP2, the light emitting elements LD may be moved between the first and second paths LN1 and LN2 (see FIG. 5), and it can be reduced or prevented that the light emitting elements LD are biasedly disposed in a specific path. After the light emitting elements LD are aligned, the solvent may be volatilized or removed through other processes, so that the light emitting elements LD can be stably arranged.

The second insulating layer INS2 may be disposed on the light emitting elements LD. For example, the second insulating layer INS2 may be partially provided on the light emitting elements LD, and expose first and second end portions EP1 and EP2 of the light emitting elements LD. In case that the second insulating layer INS2 is formed on the light emitting elements LD after the light emitting elements LD are completely aligned, the light emitting elements LD may be prevented from being separated from positions at which the light emitting elements LD are aligned.

The second insulating layer INS2 may include an organic material. However, the disclosure is not limited thereto. For example, the second insulating layer may include an inorganic material.

The first pixel electrode CNE1, the second pixel electrode CNE2, and the first intermediate electrode CTE1 may be disposed on the first and second end portions EP1 and EP2 of the light emitting elements LD, which are exposed by the second insulating layer INS2.

The first pixel electrode CNE1 may be directly disposed on a first end portion EP1 of a first light emitting element LD1, to be in contact with the first end portion EP1 of the first light emitting element LD1. The first pixel electrode CNE1 may be electrically connected to the first transistor electrode TE1 of the first transistor T1 through a contact hole or the like, which penetrates the protective layer PSV.

A first sub-intermediate electrode CTE_S1 of the first intermediate electrode CTE1 may be directly disposed on a second end portion EP2 of the first light emitting element LD1, to be in contact with the second end portion EP2 of the first light emitting element LD1. A second sub-intermediate electrode CTE_S2 of the first intermediate electrode CTE1 may be directly disposed on a first end portion EP1 of a second light emitting element LD2, to be in contact with the first end portion EP1 of the second light emitting element LD2. For example, the first intermediate electrode CTE1 may electrically connect the second end portion EP2 of the first light emitting element LD1 and the first end portion EP1 of the second light emitting element LD2 to each other.

The second pixel electrode CNE2 may be directly disposed on a second end portion EP2 of the second light emitting element LD2, to be in contact with the second end portion EP2 of the second light emitting element LD2. The second pixel electrode CNE may be electrically connected to the second power line PL2 through a contact hole or the like, which penetrates the protective layer PSV.

The first pixel electrode CNE1, the second pixel electrode CNE2, and the first intermediate electrode CTE1 may be formed of various transparent conductive materials. Accordingly, light emitted from the first and second end portions EP1 and EP2 of the light emitting elements LD may be emitted to the outside in the third direction DR3 while passing through the first pixel electrode CNE1, the second pixel electrode CNE2, and the first intermediate electrode CTE1. The transparent conductive materials may include conductive oxide such as indium tin oxide (ITO), indium zinc oxide (IZO), zinc oxide (ZnOₓ), indium gallium zinc oxide (IGZO), or indium tin zinc oxide (ITZO), a conductive polymer such as PEDOT, and the like.

In an embodiment, the first pixel electrode CNE1, the second pixel electrode CNE2, and the first intermediate electrode CTE1 may be configured as a same conductive layer. In an embodiment, the first pixel electrode CNE1, the second pixel electrode CNE2, and the first intermediate electrode CTE1 may be simultaneously formed through a same process. Thus, the number of masks may be reduced, and a manufacturing process may be simplified.

In some embodiments, an overcoat layer (not illustrated) may be disposed over the first pixel electrode CNE1, the second pixel electrode CNE2, and the first intermediate electrode CTE1. The overcoat layer may be an insulating layer including an inorganic material or an organic material. In an embodiment, the overcoat layer may have a structure in which at least one inorganic layer and at least one organic layer are alternately stacked each other. The overcoat layer may entirely cover the display element layer DPL, thereby preventing external moisture, humidity, or the like from being introduced into the display element layer DPL including the light emitting element LD. The overcoat layer may planarize a top surface of the display element layer DPL.

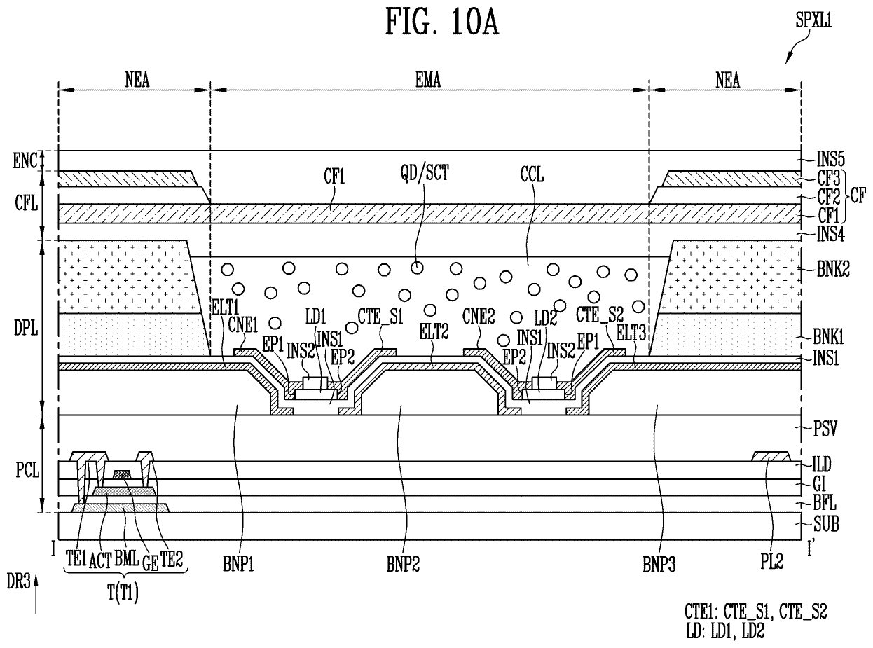

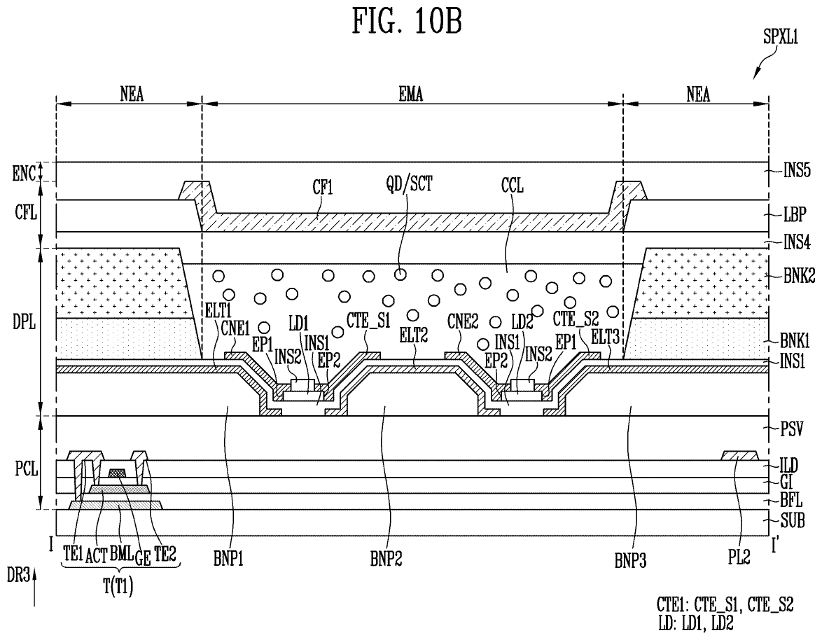

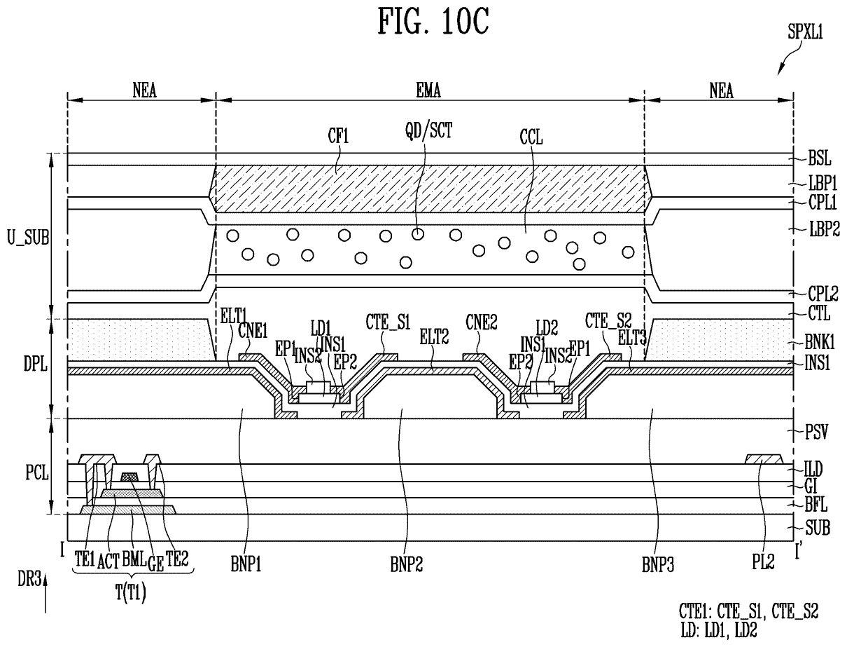

In some embodiments, the display element layer DPL may selectively include an optical layer, or the optical layer may be further disposed on the display element layer DPL. In an embodiment, the display element layer DPL may further include a color conversion layer including color conversion particles for converting light emitted from the light emitting elements LD into light of a specific color. Also, the display element layer DPL may further include a color filter for allowing only light in a specific wavelength band to be transmitted therethrough. The color conversion layer will be described with reference to FIGS. 10A to 10C.

FIGS. 10A, 10B, and 10C are each cross-sectional view illustrating the first sub-pixel taken along the line I-I′ shown in FIG. 5 in accordance with an embodiment of the disclosure.

FIGS. 10B and 10C illustrate a modified embodiment of FIG. 10A in relation to the position of a color conversion layer CCL. For example, an embodiment in which the color conversion layer CCL is located on the top of the display element layer DPL through a continuous process is disclosed in FIG. 10B, and an embodiment in which an upper substrate U_SUB including the color conversion layer CCL is located on the display element layer DPL through an adhesion process is disclosed in FIG. 10C. In relation to the embodiments shown in FIGS. 10A to 10C, portions different from those of the above-described embodiments (e.g., the embodiment shown in FIG. 7) will be described to avoid redundancy.

Referring to FIGS. 7 to 10A, a first sub-pixel SPXL1 may include a color conversion layer CCL located in an emission area EMA and a second bank BNK2 located in a non-emission area NEA.

A second bank BNK2 may be disposed on the first bank BNK1 in the non-emission area NEA of the first sub-pixel SPXL1. The second bank BNK2 may surround the emission area EMA in a plan view, and be a structure which defines the emission area EMA by defining a position at which the color conversion layer CCL is to be supplied. In an embodiment, the second bank BNK2 may be a structure which sets the emission area EMA by defining a position at which the color conversion layer CCL is supplied (or input) in the first sub-pixel SPXL1.

The second bank BNK2 may include a light blocking material. In an embodiment, the second bank BNK2 may be a black matrix. In some embodiments, the second bank BNK2 may be configured to include at least one light blocking material and/or at least one reflective material, to allows light emitted from the color conversion layer CCL to advance in the image display direction of the display device (or the third direction DR3), thereby improving the light emission efficiency of the color conversion layer CCL.

The color conversion layer CCL may be disposed on (or on top of) the first pixel electrode CNE1, the first intermediate electrode CTE1, and the second pixel electrode CNE2 in the emission area EMA surrounded by the second bank BNK2.

The color conversion layer CCL may include color conversion particles QD (or wavelength conversion particles) corresponding to a specific color. In an embodiment, the color conversion layer CCL may include color conversion particles QD for converting light of a first color (or first wavelength band), which is emitted from the light emitting element LD, into light of a second color (specific color, or second wavelength band).

In case that the first sub-pixel SPXL1 is a red pixel (or red sub-pixel), the color conversion layer CCL may include color conversion particles QD of a red quantum dot, which convert light of the first color, which is emitted from the light emitting elements LD, into light of a second color, e.g., light of red.

In case that the first sub-pixel SPXL1 is a green pixel (or green sub-pixel), the color conversion layer CCL may include color conversion particles QD of a green quantum dot, which convert light of the first color, which is emitted from the light emitting elements LD, into light of a second color, e.g., light of green.

In case that the first sub-pixel SPXL1 is a blue pixel (or blue sub-pixel), the color conversion layer CCL may include color conversion particles QD of a blue quantum dot, which convert light of the first color, which is emitted from the light emitting element LD, into light of a second color, e.g., light of blue.

In some embodiments, in case that the first sub-pixel SPXL1 is the blue pixel (or blue sub-pixel), the first sub-pixel SPXL1 may include a light scattering layer including light scattering particles SCT, instead of or in addition to the color conversion layer CCL including the color conversion particles QD. In an embodiment, in case that the light emitting elements LD emits blue series light, the first sub-pixel SPXL1 may include the light scattering layer including the light scattering particles SCT. The above-described light scattering layer may be omitted in some embodiments. In other embodiments, in case that the first sub-pixel SPXL1 is the blue pixel (or blue sub-pixel), transparent polymer may be provided instead of the color conversion layer CCL.

A fourth insulating layer INS4 may be disposed over the color conversion layer CCL and the second bank BNK2.

The fourth insulating layer INS4 may be entirely (or wholly) provided on the substrate SUB to cover the second bank BNK2 and the color conversion layer CCL. The fourth insulating layer INS4 may be directly disposed over the second bank BNK2 and the color conversion layer CCL. The fourth insulating layer INS4 may include an inorganic material. The fourth insulating layer INS4 may entirely cover the second bank BNK2 and the color conversion layer CCL, thereby preventing external moisture, humidity, or the like from being introduced into the display element layer DPL.

The fourth insulating layer INS4 may reduce a step difference occurring due to components disposed below thereof, and have a flat surface. In an embodiment, the fourth insulating layer INS4 may include an organic material. The fourth insulating layer INS4 may be a layer commonly provided in the display area DA, but the disclosure is not limited thereto.

A color filter layer CFL may be disposed on the fourth insulating layer INS4.

In the embodiment shown in FIG. 10A, the color filter layer CFL may include a color filter corresponding to a color of each of sub-pixels. For example, the color filter layer CFL may include a first color filter CF1 disposed on the color conversion layer CCL of the first sub-pixel SPXL1, a second color filter CF2 disposed on a color conversion layer CCL of a sub-pixel adjacent to the first sub-pixel SPXL1 in the first direction DR1, and a third color filter CF3 disposed on a color conversion layer CCL of another sub-pixel adjacent to the first sub-pixel SPXL1 in the first direction DR1. In an embodiment, the first, second, and third color filters CF1, CF2, and CF3 may be disposed to overlap with each other in the non-emission area NEA, to block light interference between adjacent sub-pixels. Each of the first, second, and third color filters CF1, CF2, and CF3 may include a color filter material for allowing light of a specific color, which is converted in the color conversion layer CCL, to be selectively transmitted therethrough. In an embodiment, the first color filter CF1 may be a red color filter, the second color filter CF2 may be a green color filter, and the third color filter CF3 may be a blue color filter. The above-described color filter CF may be provided on a surface of the fourth insulating layer INS4 to correspond to the color conversion layer CCL.

In the embodiment shown in FIG. 10B, the color filter layer CFL may include a first color filter CF1 and a light blocking pattern LBP. The first color filter CF1 may be located in an emission area of each of sub-pixels, and be disposed on the fourth insulating layer INS4 on the color conversion layer CCL of the corresponding sub-pixel. The light blocking pattern LBP may be located in the non-emission area NEA, and be disposed on the fourth insulating layer INS4 on the second bank BNK2 of the corresponding sub-pixel, e.g., the first sub-pixel SPXL1. The light blocking pattern LBP may be located on a surface of the fourth insulating layer INS4 to be adjacent to the first color filter CF1. The light blocking pattern LBP may overlap the first and second banks BNK1 and BNK2. The light blocking pattern LBP may include a light blocking material for preventing a light leakage defect in which light is leaked between adjacent sub-pixels. In an embodiment, the light blocking pattern LBP may include a black matrix. The light blocking pattern LBP may prevent color mixture of light emitted from each of adjacent sub-pixels.

An encap layer ENC may be provided and/or formed on the color filter layer CFL.

The encap layer ENC may include a fifth insulating layer INS5. The fifth insulating layer INS5 may be an insulating layer including an inorganic material or an organic material. The fifth insulating layer INS5 may entirely cover components located below thereof, thereby preventing external moisture, humidity, or the like from being introduced into the color filter layer CFL and the display element layer DPL.

In the display device including the first sub-pixel SPXL1 in accordance with the above-described embodiment, a color conversion layer CCL and a color filter CF may be disposed over a light emitting element LD, so that light having excellent color reproducibility may be emitted through the color conversion layer CCL and the color filter CF, thereby improving the light emission efficiency.

In an embodiment, the fifth insulating layer INS5 may be formed as a multi-layer. For example, the fifth insulating layer INS5 may include at least two inorganic layers and at least one organic layer interposed between the at least two inorganic layers. However, the material and/or structure of the fifth insulating layer INS5 may be variously changed. In some embodiments, at least one overcoat layer, at least one filler layer, and/or an upper substrate may be further disposed on the top of the fifth insulating layer INS5.

In the above-described embodiment, it has been described that the color conversion layer CCL is directly formed on the first pixel electrode CNE1, the first intermediate electrode CTE1, the second intermediate electrode CTE2, and the second pixel electrode CNE2. However, the disclosure is not limited thereto. In some embodiments, the color conversion layer CCL may be formed on a separate substrate, e.g., an upper substrate U_SUB as shown in FIG. 10C to be coupled to the display element layer DPL including first pixel electrode CNE1, the first intermediate electrode CTE1, the second intermediate electrode CTE2, and the second pixel electrode CNE2 through an intermediate layer CTL or the like.

The intermediate layer CTL may be a transparent adhesive layer (or cohesive layer), e.g., optically clear adhesive for reinforcing adhesion between the display element layer DPL and the upper substrate U_SUB, but the disclosure is not limited thereto. In some embodiments, the intermediate layer CTL may be a refractive index conversion layer for converting a refractive index of light which is emitted from light emitting elements LD and advances toward the upper substrate U_SUB, thereby improving the light emitting luminance of the pixel PXL. In some embodiments, the intermediate layer CTL may include a filler formed of an insulating material having insulative and adhesive properties.

The upper substrate U_SUB may constitute an encapsulation substrate and/or a window member of the display device. The upper substrate U_SUB may include a base layer BSL (or base substrate), a color filter layer CCL, a first color filter (or color filter CF (see FIG. 10A)), first and second light blocking patterns LBP1 and LBP2, and first and second capping layers CPL1 and CPL2.

The base layer BSL may be a rigid substrate or a flexible substrate, and the material and property of the base layer BSL are not particularly limited. The base layer BSL and the substrate SUB may be formed of a same material or different materials.

In FIG. 10C, the color conversion layer CCL and the first color filter CF1 may be disposed on a surface of the base layer BSL to face the display element layer DPL. The first color filter CF1 may be provided on the surface of the base layer BSL to correspond to the color conversion layer CCL.

A first capping layer CPL1 may be provided and/or formed between the first color filter CF1 and the color conversion layer CCL.

The first capping layer CPL1 may be located over the first color filter CF1, thereby covering the first color filter CF1. Thus, the first capping layer CPL1 may protect the first color filter CF1. The first capping layer CPL1 may be an insulating layer including an inorganic material or an organic material.

Light blocking patterns LBP1 and LBP2 may be located adjacent to the color conversion layer CCL and the first color filter CF1. The light blocking patterns LBP1 and LBP2 may be disposed on the surface of the base layer BSL to correspond to the non-emission area NEA of the first sub-pixel SPXL1. The light blocking patterns LBP1 and LBP2 may include a first light blocking pattern LBP1 and a second light blocking pattern LBP2.

The first light blocking pattern LBP1 may be located on the surface of the base layer BSL, and be located adjacent to the first color filter CF1.

The first capping layer CPL1 may be disposed on the first light blocking pattern LBP1.

The second light blocking pattern LBP2 may be disposed on a surface of the first capping layer CPL1 to correspond to the first light blocking pattern LBP1. The second light blocking pattern LBP2 may be a black matrix. The first light blocking pattern LBP1 and the second light blocking pattern LBP2 may include a same material. In an embodiment, the second light blocking pattern LBP2 may be a structure defining the emission area EMA of the first sub-pixel SPXL1. The second light blocking pattern LBP2 may have a dam structure defining an emission area EMA to which a color conversion layer CCL is to be supplied in a process of supplying the color conversion layer CCL.

A second capping layer CPL2 may be entirely provided and/or formed over the color conversion layer CCL and the second light blocking pattern LBP2.

The second capping layer CPL2 may include an inorganic material. However, the disclosure is not limited thereto. In some embodiments, the second capping layer CPL2 may include an organic material. The second capping layer CPL2 may be located over the color conversion layer CCL, thereby protecting the color conversion layer CCL from external moisture, humidity, and the like. Thus, the reliability of the color conversion layer CCL may be further improved.

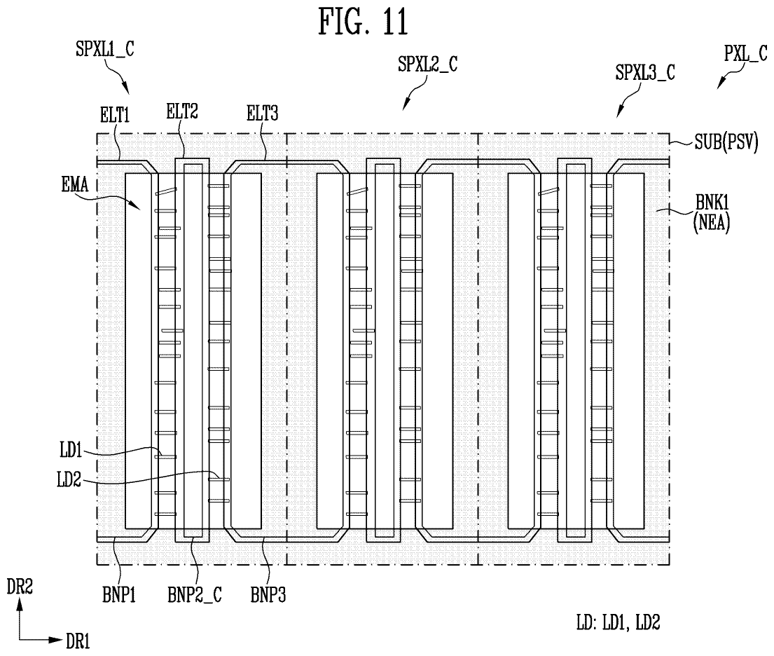

FIG. 11 is a plan view illustrating a comparative embodiment of the pixel included in the display device shown in FIG. 3. FIG. 12 is a view illustrating an image obtained by photographing the pixel shown in FIG. 11.

Referring to FIGS. 3, 5, and 11, except a second bank pattern BNP2_C, a pixel PXL_C and sub-pixels SPXL1_C to SPXL3_C, which are shown in FIG. 11, are substantially identical or similar to the pixel PXL and the sub-pixels SPXL1 to SPXL3, which are shown in FIG. 5, respectively. Therefore, overlapping descriptions will not be repeated.

The second bank pattern BNP2_C may overlap the second electrode ELT2, and extend along the second direction DR2, corresponding to the second electrode ELT2. The second bank pattern BNP2_C may divide one emission area EMA into two sub-emission areas in the first direction DR1 and extend across the emission area EMA.

As described with reference to FIG. 9, light emitting elements LD may be prepared in a form in which the light emitting elements LD are dispersed in an ink, to be supplied to the emission area EMA of the first sub-pixel SPXL1_C through an inkjet printing process, or the like. As the resolution of the display device becomes higher, the size of the first sub-pixel SPXL1_C and the emission area EMA may become smaller.

Accordingly, the number of droplets of the ink supplied to the emission area EMA may decrease, and the supply of the ink to only the center of the emission area EMA may be possible. The light emitting elements LD may be concentratedly supplied to a specific path.

Referring to FIG. 12, it can be seen in a first image IMAGE1 that the ink is supplied to the entire light emitting area along an ink boundary. However, only one first light emitting element LD1 is disposed in a left path (or first path), and about 10 second light emitting elements LD2 are disposed in a right path (or second path).

Similarly, referring to a second image IMAGE2, about 10 first light emitting elements LD1 are disposed in a left path (or first path), and only one second light emitting element LD2 is disposed in a right path (or second path).

For example, in case that a light emitting element LD is not disposed in a path or in case that a light emitting element LD is arranged in a reverse direction, a driving current may not flow through the corresponding path, and a sub-pixel may not emit light. For example, a dark spot may occur. Since an amount of current flowing through each light emitting element LD varies for each path, the sub-pixel may emit light with a luminance different from a desired luminance, and a luminance variation may be caused between sub-pixels.

Thus, the first sub-pixel SPXL1 shown in FIG. 5 may include first and second sub-patterns BNP2-1 and BNP2-2 separated from each other in the emission area EMA, and movement of the light emitting element LD between the first and second paths LN1 and LN2 may be allowed through the space between the first and second sub-patterns BNP2-1 and BNP2-2. Accordingly, a dark spot defect may be reduced, the number of light emitting elements LD aligned for each path may become uniform, and the luminance variation may be reduced. In case that a defective pixel having a dark spot defect is repaired, a repair success rate may be increased by the first and second sub-patterns BNP2-1 and BNP2-2.

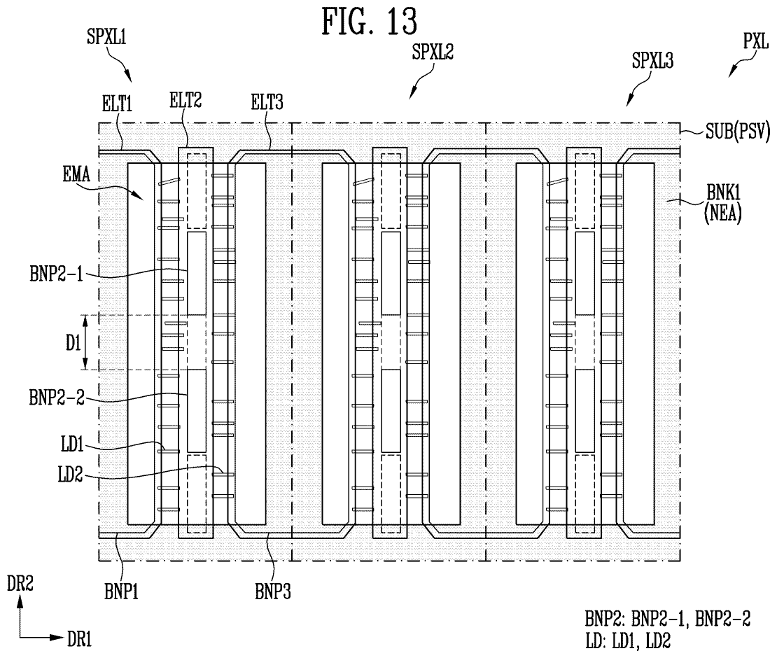

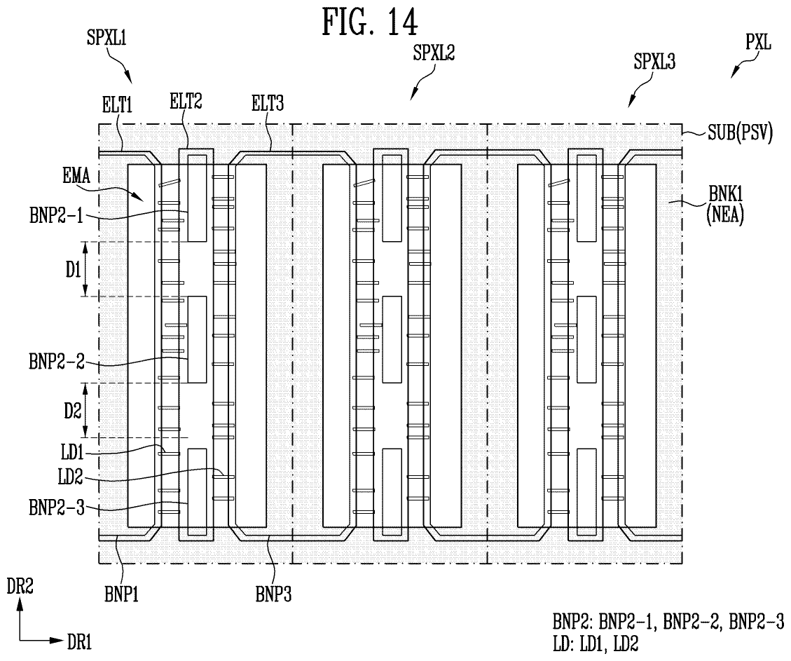

FIGS. 13 and 14 are plan views illustrating another embodiment of the pixel included in the display device shown in FIG. 3.

Referring to FIGS. 3, 5, 13, and 14, a pixel PXL shown in FIG. 13 may be substantially identical or similar to the pixel PXL shown in FIG. 5, except a size (or a length in the second direction DR2) and arrangement of sub-patterns BNP2-1 and BNP2-2 of the second bank pattern BNP2. Therefore, overlapping descriptions will not be repeated.

As shown in FIG. 13, one ends of first and second sub-patterns BNP2-1 and BNP2-2 may be spaced apart from each other at the center of the emission area EMA, and another ends of the first and second sub-patterns BNP2-1 and BNP2-2 (e.g., an uppermost portion and a lowermost portion of the second bank pattern BNP2) may be spaced apart from the first bank BNK1. For example, the first and second sub-patterns BNP2-1 and BNP2-2 shown in FIG. 13 may be disposed in an island shape in the emission area EMA.

Movement of the light emitting element LD may be allowed through a space (or discontinuous area) between the first sub-pattern BNP2-1 and the first bank BNK1 and a space (or discontinuous area) between the second sub-pattern BNP2-2 and the first bank BNK1, in addition to the space (or discontinuous area) between the first and second sub-patterns BNP2-1 and BNP2-2. A distance between the first sub-pattern BNP2-1 and the first bank BNK1 and a distance between the second sub-pattern BNP2-2 and the first bank BNK1 may be equal or similar to the first distance D1, but the disclosure is not limited thereto. As described with reference to FIG. 5, by considering a function of the second bank pattern BNP2, a total sum of the distances (or a total length of the discontinuous areas) may be about 10% to about 20% of a length of the emission area EMA in the second direction DR2.

As shown in FIG. 14, the second bank pattern BNP2 may include a first sub-pattern BNP2-1, a second sub-pattern BNP2-2, and a third sub-pattern BNP2-3, which are separated or spaced apart from each other along the second direction DR2. Lengths of the first sub-pattern BNP2-1, the second sub-pattern BNP2-2, and the third sub-pattern BNP2-3 in the second direction DR2 may be the same or be different from one another.

The first sub-pattern BNP2-1 may overlap the first bank BNK1, but the disclosure is not limited thereto. For example, as illustrated in the embodiment shown in FIG. 13, the first sub-pattern BNP2-1 may be spaced apart from the first bank BNK1.

The second sub-pattern BNP2-2 may be spaced apart from the first sub-pattern BNP2-1 with a first distance D1 in the second direction DR2.

The third sub-pattern BNP2-3 may be spaced apart from the second sub-pattern BNP2-2 with a second distance D2 in the second direction DR2. The second distance D2 may be equal or similar to the first distance D1, but the disclosure is not limited thereto. The third sub-pattern BNP2-3 may overlap the first bank BNK1, but the disclosure is not limited thereto. For example, the third sub-pattern BNP2-3 may be spaced apart from the first bank BNK1.

As described with reference to FIG. 5, by considering a function of the second bank pattern BNP2, a total sum of the first distance D1 and the second distance D2 may be about 10% to about 20% of a length of the emission area EMA in the second direction DR2.

Although a case where the second bank pattern BNP2 includes three sub-patterns BNP2-1 to BNP2-3 has been illustrated in FIG. 14, the disclosure is not limited thereto. The second bank pattern BNP2 may include four or more sub-patterns by considering a size (i.e., an area and a length) of the emission area EMA, a number of paths, and the like.

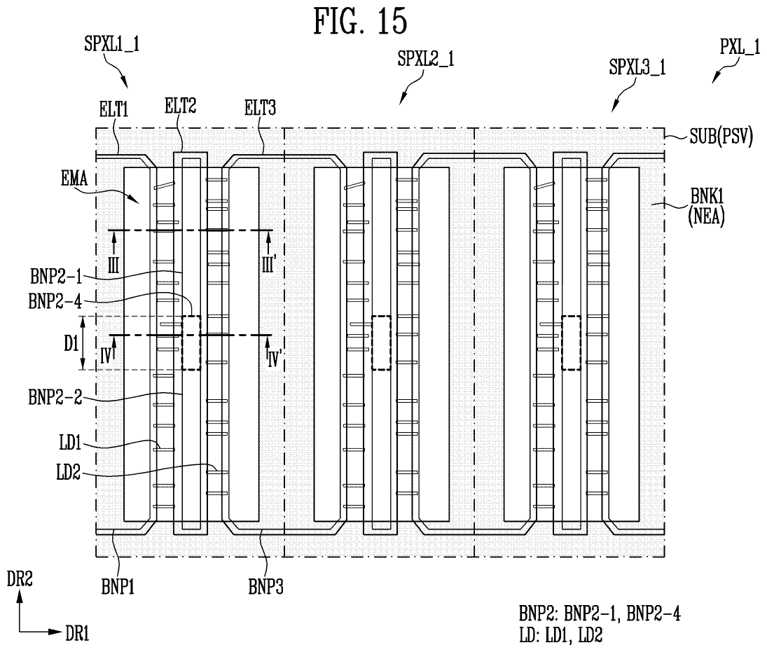

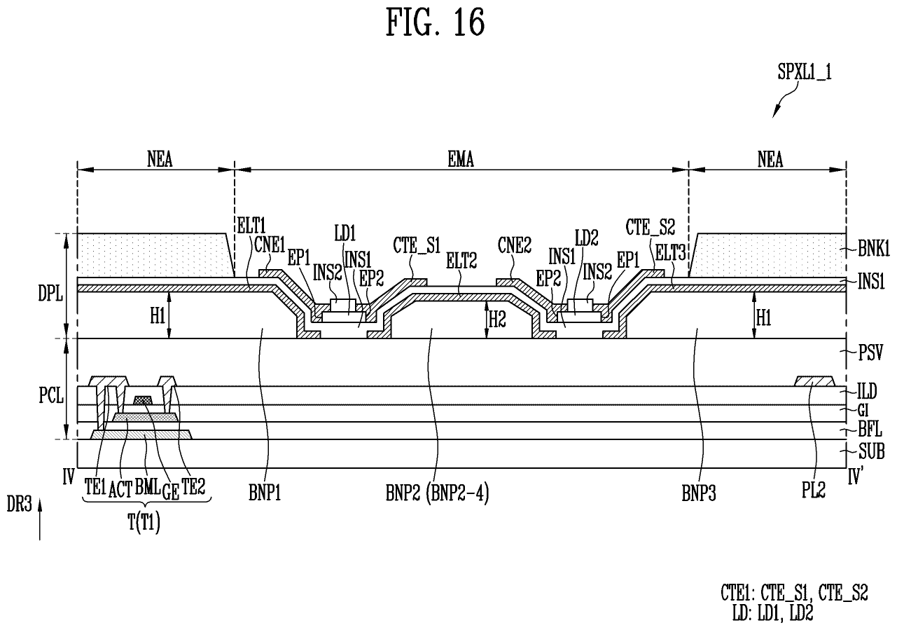

FIG. 15 is a plan view illustrating another embodiment of the pixel included in the display device shown in FIG. 3. FIG. 16 is a schematic cross-sectional view illustrating an embodiment of a first sub-pixel taken along line IV-IV′ shown in FIG. 15.

Referring to FIGS. 3, 5, and 15, except a fourth sub-pattern BNP2-4, a pixel PXL_1 and sub-pixels SPXL1_1 to SPXL3_1, which are shown in FIG. 15, are substantially identical or similar to the pixel PXL and the sub-pixels SPXL1 to SPXL3, which are shown in FIG. 5, respectively. A section taken along line III-III′ shown in FIG. 15 may be identical to the section shown in FIG. 7. Therefore, overlapping descriptions will not be repeated.

The second bank pattern BNP2 may further include a fourth sub-pattern BNP2-4 (part or area). The fourth sub-pattern BNP2-4 may be disposed between the first sub-pattern BNP2-1 and the second sub-pattern BNP2-2. A second height H2 of the fourth sub-pattern BNP2-4 in the third direction DR3 (a thickness, or a height of a top surface of the fourth sub-pattern BNP2-4) may be different from a height (or thickness) of each of the first and second sub-patterns BNP2-1 and BNP2-2. For example, in the emission area EMA, a height or thickness of the second bank pattern BNP2 may vary along the second direction DR2 (or extending direction).

As shown in FIG. 16, the second height H2 (or second thickness) of the fourth sub-pattern BNP2-4 may be lower than a first height H1 (or first thickness) or an average height of each of the first and third bank patterns BNP1 and BNP3 in the third direction DR3. The first height H1 of each of the first and third bank patterns BNP1 and BNP3 may be equal to a height of each of the first and second sub-patterns BNP2-1 and BNP2-2.

In an embodiment, the second height H2 of the fourth sub-pattern BNP2-4 may be about 40% or less of the first height H1. For example, the first height H1 may be about 2 μm to about 4 μm, or about 3 μm, and the second height H2 may be 1.5 μm or less. For example, the fourth sub-pattern BNP2-4 having the second height H2 may be formed by forming the bank patterns BNP1 to BNP3, using a halftone mask, for example, by adjusting an exposure amount with respect to the fourth sub-pattern BNP2-4, a transmittance of the halftone mask, and the like. In case that the second height H2 is 0, this embodiment may be identical to the embodiment shown in FIG. 5.

In case that the fourth sub-pattern BNP2-4 having a relatively low height is formed, movement of the light emitting element LD may be possible even though a movement speed (flow velocity, or movement amount) of the light emitting element LD between paths is decreased. In an embodiment in which the fourth sub-pattern BNP2-4 having a relatively low height is formed, the light emission efficiency of the first sub-pixel SPXL1_1 may be improved, as compared with an embodiment in which an empty space between the first and second sub-patterns BNP2-1 and BNP2-2 is included.

Although a case where the second bank pattern BNP2 includes one fourth sub-pattern BNP2-4 has been illustrated in FIG. 15, the disclosure is not limited thereto. For example, the fourth sub-pattern BNP2-4 may be applied to the discontinuous area of the second bank pattern BNP2 of the embodiment shown in FIGS. 13 and 14. The embodiments shown in FIGS. 5 and 13 to 15 may be combined. For example, the second bank pattern BNP2 may include both the discontinuous area shown in FIG. 5 and the fourth sub-pattern BNP2-4 shown in FIG. 15.

In accordance with the disclosure, the display device may include bank patterns for changing a surface profile of electrodes (or reflective electrodes). A second bank pattern for partitioning an emission area or a path may extend discontinuously, and may include at least one discontinuous area. Thus, in a manufacturing process of the display device, a light emitting element may move between emission areas or between paths through the discontinuous area, the number of light emitting elements aligned for each path may become uniform, and a luminance variation caused by a number deviation of light emitting elements may be reduced.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first bank defining an emission area;
a first bank pattern, a second bank pattern, and a third bank pattern, each disposed in the emission area, arranged in a first direction, and extending in a second direction intersecting the first direction;
a first electrode, a second electrode, and a third electrode, respectively overlapping the first, second, and third bank patterns in a plan view; and
light emitting elements arranged between the first electrode and the second electrode and between the second electrode and the third electrode,
wherein the second bank pattern is discontinuously disposed.

2. The display device of claim 1, wherein the second bank pattern includes at least one discontinuous area.

3. The display device of claim 2, wherein the at least one discontinuous area is located at a center of the emission area.

4. The display device of claim 2, wherein a length of the at least one discontinuous area in the second direction is in a range of about two times to about five times of a length of each of the light emitting elements.

5. The display device of claim 1, wherein the second bank pattern includes a first sub-pattern and a second sub-pattern, which are spaced apart from each other in the second direction.

6. The display device of claim 5, wherein the second electrode continuously extends from the first sub-pattern to the second sub-pattern and covers an area between the first sub-pattern and the second sub-pattern.

7. The display device of claim 5, wherein a distance between the first sub-pattern and the second sub-pattern in the second direction is in a range of about two times to about five times of a length of each of the light emitting elements.

8. The display device of claim 7, wherein the distance between the first sub-pattern and the second sub-pattern is in a range of about 10 μm to about 20 μm.

9. The display device of claim 5, further comprising:
a first contact electrode overlapping the first electrode in a plan view and electrically connected to first end portions of some of the light emitting elements; and
a second contact electrode overlapping the second electrode in a plan view and electrically connected to second end portions of the some of the light emitting elements.

10. The display device of claim 9, wherein the second contact electrode has a bent shape in an area between the first sub-pattern and the second sub-pattern in a plan view.

11. The display device of claim 9, further comprising:
an insulating layer disposed between the first and second contact electrodes and the first and second electrodes,
wherein the first and second contact electrodes are electrically insulated from the first and second electrodes.

12. The display device of claim 5, wherein at least one of the first and second sub-patterns overlaps the first bank in a plan view.

13. The display device of claim 5, wherein the first and second sub-patterns are spaced apart from the first bank in a plan view.

14. The display device of claim 1, further comprising:
a color conversion pattern disposed on the light emitting elements, converting a wavelength band of light incident from the light emitting elements, and emitting the light having the converted wavelength band; and
a color filter disposed on the color conversion pattern.

15. A display device comprising:
a first bank pattern, a second bank pattern, and a third bank pattern, each disposed in an emission area, arranged in a first direction, and extending in a second direction intersecting the first direction;
a first electrode, a second electrode, and a third electrode, respectively disposed on the first, second, and third bank patterns;
a first bank disposed on the first to third electrodes and defining the emission area; and
light emitting elements arranged between the first electrode and the second electrode and between the second electrode and the third electrode, wherein
light emitted from the light emitting elements is reflected by the first to third electrodes on the first to third bank patterns to advance in a third direction intersecting the first direction and the second direction,
the second bank pattern includes a portion, and
the portion of the second bank pattern and another portion of the second bank pattern have different thicknesses in the third direction.

16. The display device of claim 15, wherein a thickness of the portion of the second bank pattern in the third direction is less than an average thickness of the second bank pattern in the third direction.

17. The display device of claim 16, wherein the thickness of the portion of the second bank pattern is less than or equal to about 40% of a thickness of the another portion of the second bank pattern in the third direction.

18. The display device of claim 16, wherein a length of the portion of the second bank pattern in the second direction is in a range of about two times to about five times of a length of each of the light emitting elements.

19. The display device of claim 15, wherein the second bank pattern overlaps the first bank in a plan view and extends across the emission area.

20. The display device of claim 15, further comprising:
a color conversion pattern disposed on the light emitting elements, converting a wavelength band of the light emitted from the light emitting elements, and emitting the light having the converted wavelength band; and
a color filter disposed on the color conversion pattern.
